(19) United States
(12) Patent Application Publication
(10) Pub. No.: US 2026/0040822 A1
(43) Pub. Date: Feb. 5, 2026

(54) ELECTRICAL ENERGY GENERATION AND STORAGE SYSTEM WITH SUPERCONDUCITIVITY

(71) Applicant: Jon Murray Schroeder, Leander, TX (US)

(72) Inventor: Jon Murray Schroeder, Leander, TX (US)

(73) Assignee: Juanita Castorena, Leander, TX (US)

(21) Appl. No.: 19/271,158

(22) Filed: Jul. 16, 2025

Related U.S. Application Data
(63) Continuation-in-part of application No. 19/137,988.
Application No. 19/137,988 is a continuation of application No. 18/067,465, filed on Dec. 16, 2022, now Pat. No. 12,041,852.

(51) Int. Cl. H10N 10/17; H10N 10/855

(52) U.S. Cl. CPC H10N 10/17; H10N 10/8552

(57) ABSTRACT

Apparatus and associated methods relate to a thermoelectric device having a superconducting generator ring. In an illustrative example, a thermoelectric device may include a differential generator supply and a thermoelectric generator ring. The thermoelectric generator ring, for example, may be configured to generate an electric current based on a differential temperature received from the differential temperature supply. For example, the thermoelectric generator ring may include a number of thermoelectric coupons forming a ring on a horizontal plane. Each of the thermoelectric coupons may include an n-type impurity diffused silicon semiconductor (IDSS) and an p-type IDSS. For example, the impurities may be distributed in the IDSS at a predetermined concentration distribution, at which a forward bias voltage of the IDSS is below a predetermined target voltage (e.g., 20 mV) Various embodiments may advantageously generate a low-voltage loss high electric current based on an applied temperature differential at the thermoelectric coupons.

### CROSS-REFERENCE TO RELATED APPLICATIONS

This application is a continuation-in-part, and claims the benefit of, U.S. application Ser. No. 19/137,988 titled “Superconducting Type Silicon Thermoelectric Generator,” filed by Jon Murray Schroeder, on Jun. 11, 2025, which is a 371 of, and claims the benefit of, PCT Application Ser. No. PCT/US2023/084396, titled “Superconducting Type Silicon Thermoelectric Generator,” filed by Jon Murray Schroeder, on Dec. 15, 2023, which claims the benefit of U.S. application Ser. No. 18/067,465, titled “Superconducting Type Silicon Thermoelectric Generator,” filed by Jon Murray Schroeder, on Dec. 16, 2022.

The subject matter of this application may have common inventorship with and/or may be related to the subject matter of the following:
. U.S. application Ser. No. 18/067,465, titled “SILICON THERMOELECTRIC GENERATOR,” filed by Jon Murray Schroeder, on Dec. 16, 2022, issued as U.S. Pat. No. 12,041,852.
U.S. application Ser. No. 10/154,757, titled “Torus semiconductor thermoelectric device,” filed by Jon Schroeder, et al., on May 23, 2002.
U.S. application Ser. No. 10/340,885, titled “Torus semiconductor thermoelectric chiller,” filed by Jon Schroeder, et al., on Jan. 13, 2003.
U.S. application Ser. No. 11/259,922, titled “Solid state thermoelectric power converter,” filed by Jon Murray Schroeder, et al., on Oct. 28, 2005, issued as U.S. Pat. No. 8,101,846.
U.S. application Ser. No. 11/517,882, titled “Thermoelectric device with make-before-break high frequency converter,” filed by Jon Murray Schroeder, et al., on Sep. 8, 2006, issued as U.S. Pat. No. 8,183,456.
U.S. application Ser. No. 12/454,378, titled “Solar home electrification with grid connection,” filed by Jon Murray Schroeder, et al., on May 18, 2009, issued as U.S. Pat. No. 8,354,582.
U.S. application Ser. No. 12/454,379, titled “Solar thermoelectric power station,” filed by Jon Murray Schroeder, et al., on May 18, 2009.
U.S. application Ser. No. 12/454,376, titled “Solar to electric system,” filed by Jon Murray Schroeder, et al., on Sep. 18, 2009.
U.S. application Ser. No. 14/179,549, titled “Thermoelectric evaluation and manufacturing methods,” filed by Jon Murray Schroeder, et al., on Feb. 12, 2014.

This application incorporates the entire contents of the foregoing application(s) herein by reference.

### TECHNICAL FIELD

Various embodiments relate generally to methods and systems related to thermoelectric generators and thermoelectric energy storage.

### BACKGROUND

Superconductivity describes an effect when there is a complete or near complete disappearance of electrical resistance in solids. In some examples, a superconductivity state (Te) of a solid may be achieved when the solid is cooled below a characteristic temperature associated with the solid. The characteristic temperature, for example, may be called a transition temperature or critical temperature (Tc).

For example, the Te of mercury happens at −4.15-Kelvin, or −268.85 Centigrade as discovered by Dutch physicist Heike Kamerling Onnes in 1917. This was discovered several years after the discovery of liquid helium. Until 1983, a highest record of Tc super conductivity was −23.3-K for an alloy Nb3Ge. High temperature superconductors were also discovered in 1986, for example, having a critical temperature of −89K to 93 K, with the parent structure YBa2Cu3O7. At the present time, the record transition temperature may be 134 Kelvin for the superconducting material compound (TBCCO). Nonetheless, Tc of any alloy and elements are long way from a room temperature (e.g., 25 C).

### SUMMARY

Apparatus and associated methods relate to a thermoelectric device having a superconducting generator ring. In an illustrative example, a thermoelectric device may include a differential generator supply and a thermoelectric generator ring. The thermoelectric generator ring, for example, may be configured to generate an electric current based on a differential temperature received from the differential temperature supply. For example, the thermoelectric generator ring may include a number of thermoelectric coupons forming a ring on a horizontal plane. Each of the thermoelectric coupons may include an n-type impurity diffused silicon semiconductor (IDSS) and a p-type IDSS. For example, the impurities may be distributed in the IDSS at a predetermined concentration distribution, at which a forward bias voltage of the IDSS is below a predetermined target voltage (e.g., 20 mV) Various embodiments may advantageously generate a low-voltage loss high electric current based on an applied temperature differential at the thermoelectric coupons.

Various embodiments may achieve one or more advantages. For example, some embodiments may advantageously rectify the generated current into a power grid compatible power. For example, some embodiments may advantageously be transportable by land, air, and/or sea to provide a mobile power supply. Some embodiments may, for example, advantageously convert salt water into freshwater. Some embodiments may, for example, advantageously receive sea water and carbon input to generate jet fuel.

The details of various embodiments are set forth in the accompanying drawings and the description below. Other features and advantages will be apparent from the description and drawings, and from the claims.

### BRIEF DESCRIPTION OF THE DRAWINGS

FIG. 1 depicts an exemplary solid state generator (SSG) employed in an illustrative use-case scenario.

FIG. 2 is a block diagram depicting an exemplary thermoelectric generator ring with a closed up view in an exemplary current generation coupon.

FIG. 3A, FIG. 3B, and FIG. 3C depict an exemplary structure, carrier concentration, thermal resistance, and electron mobility of an exemplary p-type semiconductor of the current generation coupon as described with reference to FIG. 2.

FIG. 3D and FIG. 3E depict an exemplary structure and carrier concentration of an exemplary n-type semiconductor of the current generation coupon as described with reference to FIG. 2.

FIG. 4A and FIG. 4B shows exemplary transfer characteristics of an exemplary p-type solid wafer as described with reference to FIGS. 3A-3C.

FIG. 5 shows exemplary deposition temperature selections based on solid solubility of a selected carrier.

FIG. 6 is a flowchart illustrating an exemplary current generation coupon manufacturing method.

FIG. 7 is a flowchart illustrating an exemplary method for selecting parameters for manufacturing a forward bias regulated semiconductor.

FIG. 8 depicts an exemplary thermal energy storage system (TESS) in an illustrative use-case scenario.

FIG. 9 depicts an exemplary freshwater production system (FPS) in an illustrative use-case scenario.

FIG. 10 depicts an exemplary carbon neutral fuel synthesizing system (CNFSS) in an illustrative use-case scenario.

FIG. 11A, FIG. 11B, FIG. 11C, and FIG. 11D depict exemplary progress of varying forward bias voltage to achieve a highly conducting current generation coupon (CGC).

FIG. 12A and FIG. 12B depict an exemplary structure of a highly conducting CGC.

FIG. 13A, FIG. 13B, and FIG. 13C are block diagrams showing an exemplary thermal energy generation and storage system (TEGASS).

FIG. 14 depicts an exemplary solid-state generation system with an excess energy storage.

FIG. 15 shows an exemplary packaged solid-state superconducting thermoelectric device (PSSTD) in an illustrative use-case scenario.

FIG. 16 depicts an exemplary hybrid jet engines coupled to an SSG.

FIG. 17 is a flowchart showing an exemplary superconducting ring manufacturing method.

FIG. 18 illustrates a flowchart of an exemplary solid-state electricity generation method.

Like reference symbols in the various drawings indicate like elements.

### DETAILED DESCRIPTION OF ILLUSTRATIVE EMBODIMENTS

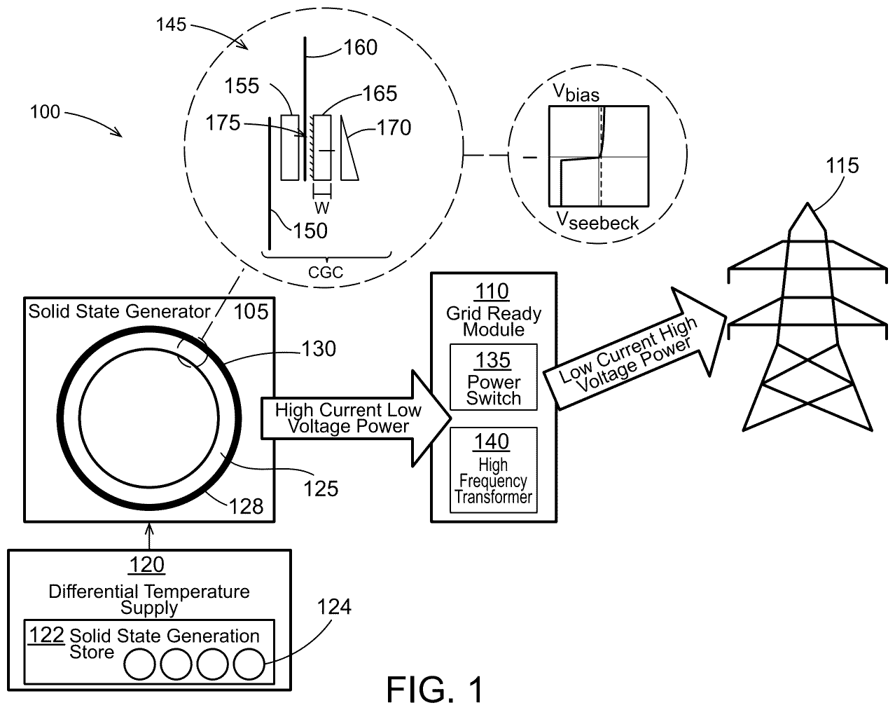

FIG. 1 depicts an exemplary solid-state generator (SSG) employed in an illustrative use-case scenario. In this scenario 100, a SSG 105 is connected to a grid ready module 110. The SSG 105 may generate a high current low voltage DC power to the grid ready module 110. For example, the generated DC power may have a voltage of less than 0.1V. For example, the generated DC power may have a voltage less than 0.05V. As shown, the grid ready module 110 converts the high current low voltage DC power to a high voltage low current AC power to supply a power grid 115. For example, the power grid 115 may be a power transmission system supplying electric power to a region (e.g., a city, an island, a state). For example, the high voltage AC power may be 200-240V. For example, the high voltage AC power may be 200-240V. For example, the high voltage AC power may be 100-120V. For example, the high voltage AC power may be 50 kV to 800 kV. For example, the high voltage AC power may be single phase. For example, the high voltage AC power may be three-phased.

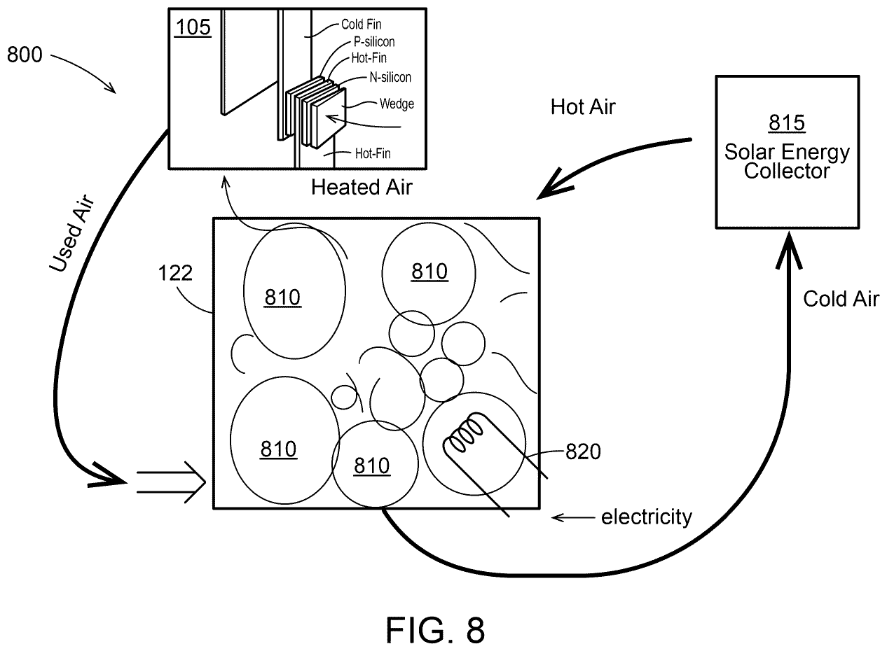

As shown, the SSG 105 is operably coupled to a differential temperature supply (DTS 120). For example, the DTS 120 may include a heat source to generate a temperature differential to the SSG 105. In some implementations, the heat source may include a renewable energy source. For example, the heat source may include generating heat using solar energy. For example, the heat source may include transferring heat to the SSG 105 using a thermal energy storage device as described further with reference to FIG. 8. Various embodiments and applications of the SSG 105 are described in Inventor's previously filed U.S. patent application Ser. No. 11/517,882, titled “Thermoelectric device with make-before-break high frequency converter,” filed by Jon Murray Schroeder, et al., on Sep. 8, 2006, issued as U.S. Pat. No. 8,183,456. The foregoing application is entirely incorporated herein by reference.

The SSG 105 includes a thermoelectric split ring (TESR 125) enclosed in a ring housing 130. In some implementations, the TESR 125 may induce a high electric current upon receiving a differential temperature supplied from the DTS 120. For example, the TESR 125 may produce 1000-1 million amps of current based on the temperature differential.

In some implementations, the DTS 120 may include a solid-state generation store (SSGS 122). For example, the SSGS 122 may include (electrically) heated insulated bauxite. In some implementations, the DTS 120 may include a fluid circulating system that recirculates hot air produced from the SSGS 122 as a working fluid. In this example, the SSGS 122 includes storage materials 124 (e.g., bauxite alumina rocks) to store thermal energy. In some implementations, the SSGS 122 may include an insulated wall to maintain the thermal energy kept in the storage materials 124.

The grid ready module 110 includes a power switch 135 and a high frequency transformer 140. In some implementations, the power switch 135 may be configured to control the generated current in the TESR 125. For example, the power switch 135 may include a series inductance to control the generated current. In various implementations, the power switch 135 may include enough impedance to advantageously limit the generated current to prevent a Lorentz force breaking apart the TESR 125. In this example, the SSG 105 includes a strap 128 to reinforce a mechanical structure of the TESR 125.

In some implementations, the power switch 135 may switch the generated current (e.g., by opening and shorting the TESR 125) through two, one turn primary windings at 200 kHz to generate a high frequency, low voltage input to the high frequency transformer 140. For example, the high frequency transformer 140 may be a step-up transformer transforming the high current low voltage power to the low current high voltage power. In some implementations, the high frequency transformer 140 may include a pulse-width-modulation (PWM) rectifier to convert the low current high voltage input power to be compatible with the power grid 115 in voltage, frequency, and phase. For example, the PWM rectifier may modulate a square wave DC input power into a sine wave. For example, an output of the PWM rectifier may advantageously be connected to the power grid 115 in-frequency to add power to a, for example, grid transformer.

In some implementations, the power switch 135 may include multiple (e.g., stacked) switches to process the high current low voltage power from the SSG 105. For example, at 200,000 Hz, the power switch 135 may include 50 switches. For example, at 200,000 Hz, the power switch 135 may power a switching power supply, in make before break mode. For example, each of the 50 switches may handle 20,000 Amps of current. For example, the grid ready module 110 may generate an output power of 1-MW for each of the SSG 105.

In some implementations, the high frequency transformer 140 may be a Ferrite high frequency transformer.

In some implementations, the high frequency transformer 140 may include more turns on a secondary coil than a primary coil. For example, the primary coil may include one turn of copper wire. For example, the secondary coil may include 28 turns of copper wire.

For example, the primary coil may include a minimal inductance. For example, the high frequency transformer 140 may receive a (near) square-wave of current on the primary coil without blowing the power switch 135. In some implementations, on the secondary coil, the high frequency transformer 140 may generate a high voltage output based on a step-up turn ratio. For example, a current generated at the secondary coil may decrease from the primary coil by the step-up turn ratio.

In this example, the TESR 125 includes more than one current generation coupon (CGC 145). For example, the TESR 125 may include sixty CGC 145. In other examples, more or less CGC 145 (e.g., 40, 70, 90, 120) may be included in the TESR 125. For example, the CGC 145 may be surrounded and reinforced by a strap to advantageously maintain the structure when the TESR 125 expand when the CGCs 145 of the TESR 125 are heated up by the DTS 120. The CGC 145 includes a cold metal fin 150, a p-silicon solid wafer 155, a hot metal fin 160, and an n-silicon solid wafer 165. A neutral wedge 170 is included in each of the CGC 145 to align the CGC 145 into a ring shape. In some implementations, the neutral wedge 170 and the cold metal fin 150 may be combined. For example, the cold metal fin 150 may be shaped to facilitate formation of a split ring.

The hot metal fin 160, for example, may be coupled to the heat source of the DTS 120 to conduct high temperature to the p-silicon solid wafer 155. In some implementations, the hot metal fin 160 may be coupled to a boiler to receive heat energy. For example, the cold metal fin 150 may be coupled to a chilling source of the DTS 120 to remove high temperature to CGCs 145. In some implementations, the cold metal fins 150 may be air cooled to 55° C.

In some implementations, the p-silicon solid wafer 155 and the n-silicon solid wafer 165 may be a silicon wafer with a manipulated forward bias voltage based on an effective amount of impurities diffusion in the wafers. For example, forward bias voltages (V_{bias}) of the p-silicon solid wafer 155 and the n-silicon solid wafer 165 may be reduced to a level less than a Seebeck voltage. (V_{seebeck}). Accordingly, the CGC 145 may advantageously include extremely low resistance to a circulating current when heat is received at the hot metal fin 160.

For example, the p-silicon solid wafer 155 and/or the n-silicon solid wafer 165 may include 7 Ohm-cm resistance. For example, with 0.05″ of thickness, the p-silicon solid wafer 155 and/or the n-silicon solid wafer 165 may include 0.02V-0.04V of Seebeck voltage at 50° C.-100° C. temperature differential. For example, the Seebeck voltage may be directly proportional to the temperature differential.

As shown in this example, the n-silicon solid wafer 165 may include a contact surface 175 configured to contact the hot metal fin 160. For example, a ratio of a surface area (of the contact surface 175) to a width (w) of the n-silicon solid wafer 165 may be high (e.g., higher than 1:20, 1:50, 1:100, 1:200). For example, the high surface area to width ratio may advantageously increase current induction efficiency.

In some implementations, the SSG 105 may be operated as a 1-MW solid state, 3 phase 50/60 Hz generator. For example, the SSG 105 may be operated using low carbon waste heat as described in further details with reference to FIG. 8. For example, the CGC 145 made with silicon wafers may advantageously be resilient to make the SSG 105 suitable for transportation.

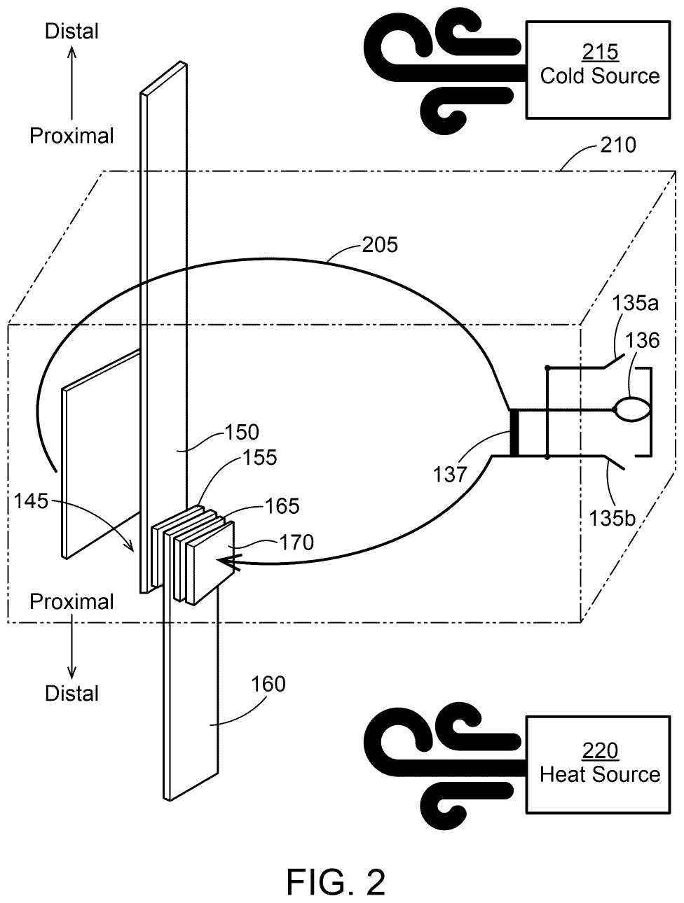

FIG. 2 is a block diagram depicting an exemplary thermoelectric generator split ring with a closed up view in an exemplary current generation coupon. In this example, multiple CGCs 145 are arranged to form a split ring 205 on a horizontal plane. The split ring 205 is enclosed in a housing 210. As shown, each CGC 145 includes a hot metal fin 160 and a cold metal fin 150 that extends orthogonal to the horizontal plane. In some implementations, the cold metal fin 150 and the hot metal fin 160 may extend 180° with each other. As shown, the cold metal fin 150 is extended upwards to receive cold fluid from a cold source 215. For example, the hot metal fin 160 is extended downwards to receive hot fluid from a heat source 220.

In some implementations, each CGC 145 may include impurities diffused silicon semiconductors (IDSS). For example, the CGC 145 may include P+ impurities in the p-silicon solid wafer 155 and n-impurities in the n-silicon solid wafer 165. In various implementations, when a temperature differential is applied in a forward direction (e.g., with higher temperature at the hot metal fin 160 and cooler temperature at the cold metal fin 150), the IDSS of the CGC 145 may induce a current flow. In some embodiments, the IDSS may be configured to include a close to zero resistance such that each of the CGC 145 may be superconducting. For example, the diffused silicon semiconductor (IDSS) may include impurities at a predetermined concentration distribution, such that a forward bias voltage of the IDSS is below a predetermined voltage. By combining a number of CGC 145, each feeding an induced electric current in a split ring, for example, the SSG 105 may generate a super high electric current (e.g., 8000 A).

As depicted, the power switch 135 includes a first terminal 135a and a second terminal 135b, each connected to a second coil 136. As depicted, the power switch 135 alternately connects a first lead of the SSG 105 to the second coil 136 through either the first terminal 135a or the second terminal 135b. A second lead of the SSG 105 is connected to a common terminal of the second coil 136. Accordingly, the sequential connection of the first lead of the SSG 105 to the power switch 135 through the first terminal 135a and the second terminal 135b may advantageously convert a single direction of current flow in the SSG 105 to alternating current through the second coil 136. Accordingly, by way of example and not limitation, the SSG 105 may advantageously be controlled to output alternating current at a predetermined frequency (e.g., 50 Hz, 60 Hz).

In this example, the split ring 205 may be connected by a thermally conducting electrical insulator 137. For example, the thermally conducting electrical insulator 137 may include a mica. For example, the thermally conducting electrical insulator 137 may include 1 inch square surfaces coupled to each end of the split ring 205. For example, the thermally conducting electrical insulator 137 may be 0.05″ thick. In some implementations, the thermally conducting electrical insulator 137 may force the electric current generated in the split ring to the second coil 136 of the high frequency transformer 140. In some implementations, the insulator (e.g., mica) may prevent destruction of the TESC.

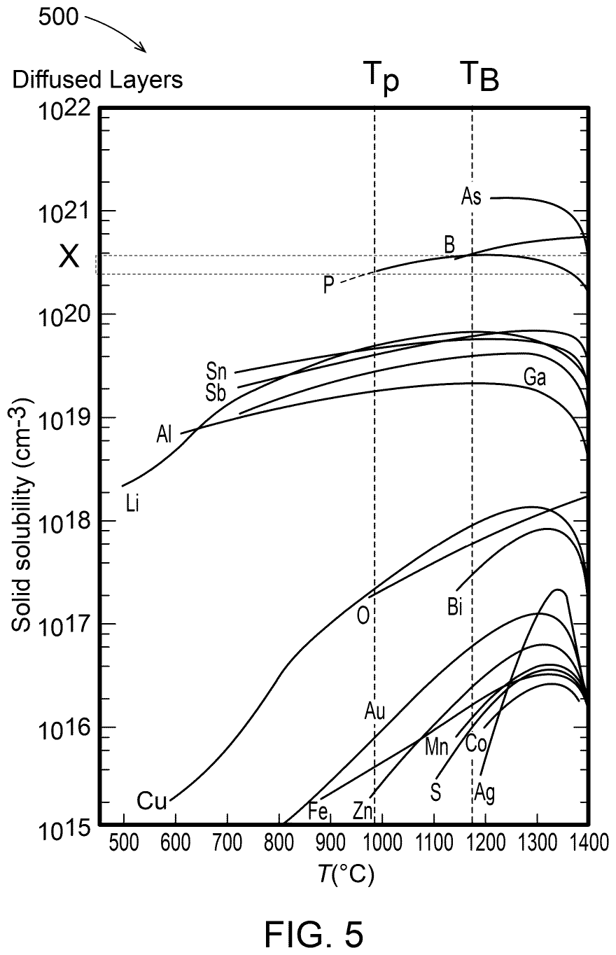

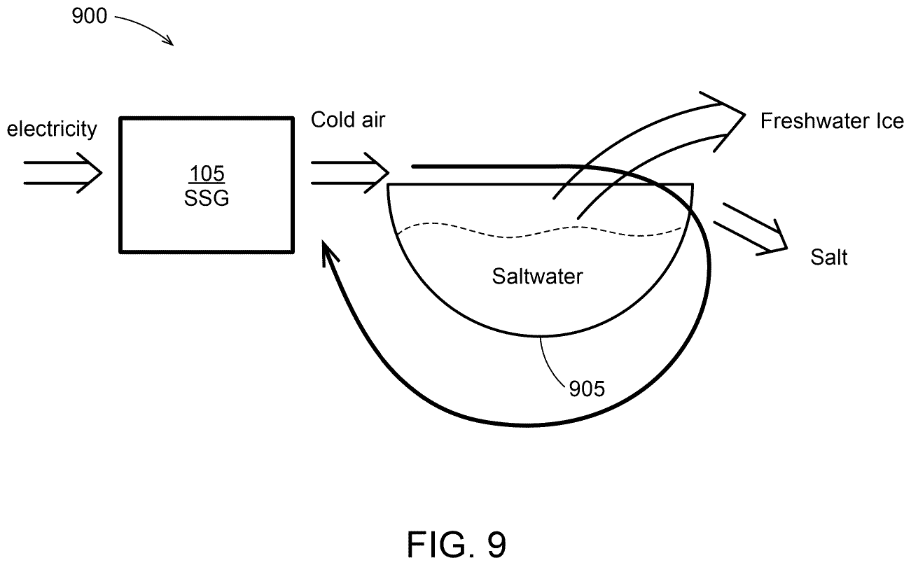

In various implementations, the high frequency transformer 140 may include two, one-turn coils. Some exemplary embodiments of connections between the split ring 205 and the high frequency transformer 140 are discussed with reference to FIGS. 5 and 9 the Inventor's own U.S. patent application Ser. No. 14/229,838, titled “Thermoelectric device with make-before-break high frequency converter,” filed by Jon Murray Schroeder, et al., on Mar. 29, 2014. The foregoing application is entirely incorporated herein by reference.

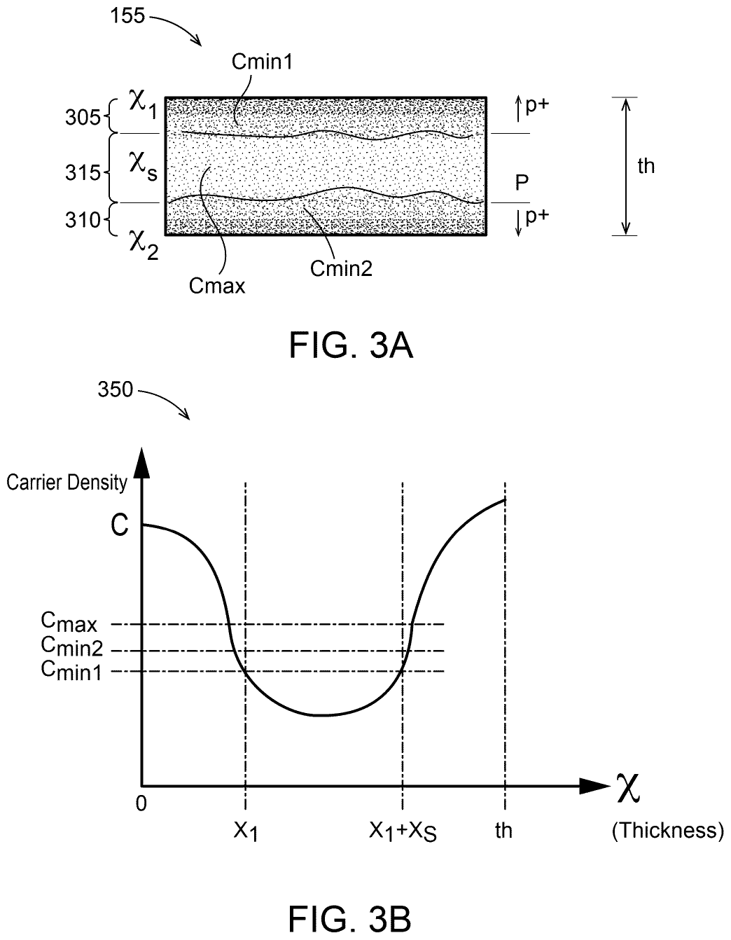

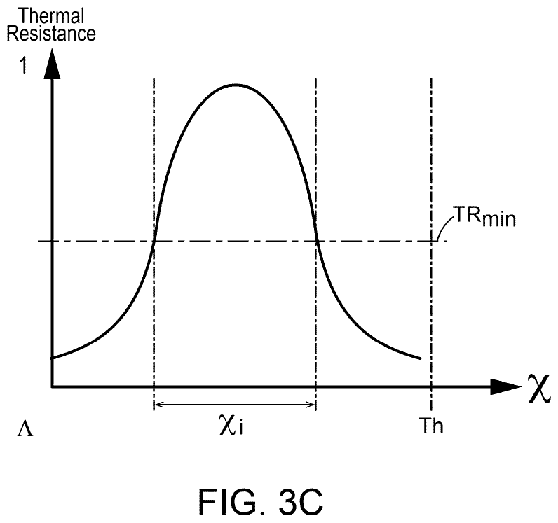

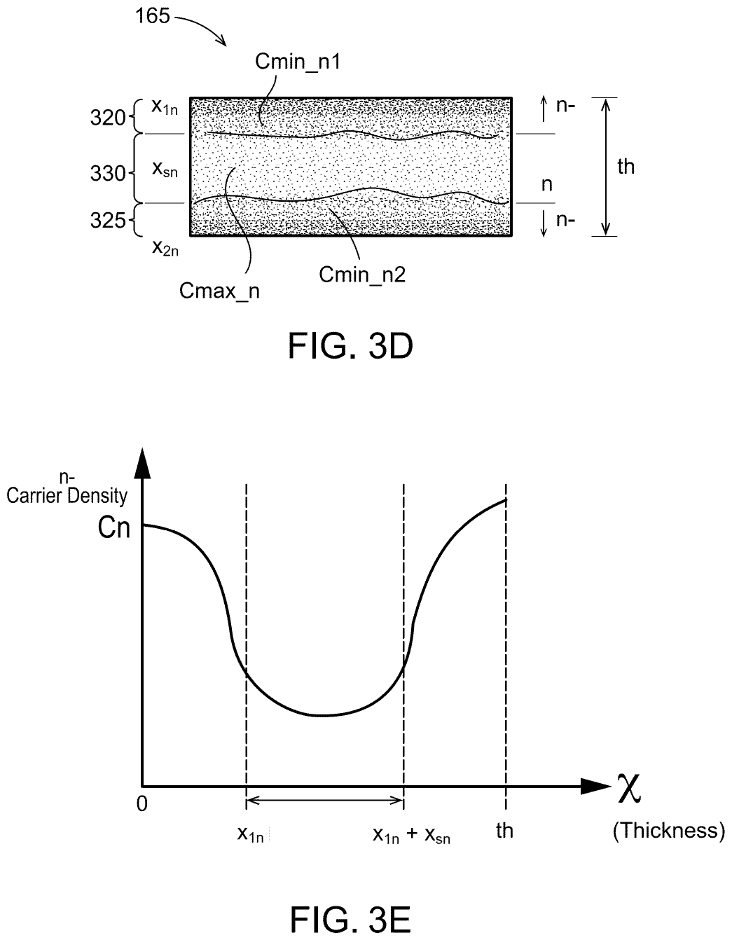

FIG. 3A, FIG. 3B, and FIG. 3C depict an exemplary structure, carrier concentration, thermal resistance, and electron mobility of an exemplary p-type silicon wafer of the current generation coupon (CGC 145) as described with reference to FIG. 2. As shown in FIG. 3A, a p-silicon solid wafer 155, having a total thickness (th), includes an entrance layer 305, an exit layer 310, and a p-type substrate 315. For example, the total thickness may be 1200-1600 microns. The entrance layer 305 has a thickness of X₁. The exit layer 310 has a thickness of X₂. The p-type substrate 315 has a thickness of Xₛ. Some exemplary thickness of X₁ and X₂ are described with reference to FIG. 5.

As an illustrative example, th may be 1400 microns. By way of example and not limitation, X₁ may be 10 microns. X₂ may, for example, be 10 microns. For example, X_{S} may be 1380 microns.

The entrance layer 305 includes p+ carriers with a concentration of at least more than a predetermined concentration C_min1. The exit layer 310 includes p+ carriers with a concentration of at least more than a predetermined concentration C_min2. The p-type substrate 315 includes p+ carriers with a concentration no more than a predetermined concentration C_max. In various examples, the p-type substrate 315 may include nearly no p+ carriers.

As shown, the p-silicon solid wafer 155 includes a p+-p junction in the entry region and a p-p+ junction in the exit region. The n-silicon solid wafer 165 includes a n+-n junction in the entry region and a n-n+ junction in the exit region.

As shown in FIG. 3B, a predetermined concentration distribution 350 is shown. In this example, the C_min2>C_max and C_min1>C_max. In various implementations, the predetermined concentrations C_min1 and C_min2 may advantageously reduce the forward bias voltage of the p-silicon solid wafer 155. For example, a higher concentration of the selected impurities may be at a surface (e.g., in regions 0-X₁ and X₁+X_{S}-th) than a concentration of the selected impurities in a center of thickness (e.g., in a region X₁-X₁+X_{S}).

In various implementations, the p-silicon solid wafer 155 may be coupled to the cold metal fin 150 at the entrance layer 305 and the hot metal fin 160 at the exit layer 310. In operation, for example, a temperature differential may be applied (e.g., by the DTS 120) between the entrance layer 305 and the exit layer 310 to induce an electric current to flow into the entrance layer 305 and out of the exit layer 310. As shown in FIG. 3C, the p-type substrate 315 may include a thermal resistance above a predetermined minimum level (T_{Rmin}) to advantageously generate a heat flow (e.g., a temperature differential) between two sides of the p-silicon solid wafer 155 to generate electric current.

FIG. 3D and FIG. 3E depict an exemplary structure and carrier concentration of an exemplary n-type semiconductor of the current generation coupon as described with reference to FIG. 2. As shown in FIG. 3D, the n-silicon solid wafer 165 includes an entrance layer 320, an exit layer 325, and a n-type substrate 330. The entrance layer 320 has a thickness of X₁ₙ. The exit layer 325 has a thickness of X₂ₙ. The p-type substrate 330 has a thickness of Xₛₙ.

As an illustrative example, th may be 1400 microns. By way of example and not limitation, X₁ₙ may be 10 microns. X₂ₙ may, for example, be 10 microns. For example, X_{Sn} may be 1380 microns.

Similar to the p-silicon solid wafer 155 as described with reference to FIGS. 3A-B. The entrance layer 320 includes n-carriers with a concentration of at least more than a predetermined concentration C_{min1_n}. The exit layer 325 includes n-carriers with a concentration of at least more than a predetermined concentration C_{min2_n}. The n-type substrate 330 includes n-carriers with a concentration no more than a predetermined concentration C_{max_n}. In various examples, the n-type substrate 330 may include nearly no n-carriers.

As shown in FIG. 3E, the Cmin_n2>Cmax_n and Cmin_1n>C_max_n. In various implementations, the predetermined concentrations Cmin_n1 and Cmin_n2 may advantageously reduce the forward bias voltage of the p-silicon solid wafer 155. As described in FIG. 2, the n-silicon solid wafer 165 may be coupled to the cold metal fin 150 at the exit layer 325 and the hot metal fin 160 at the entrance layer 305. Accordingly, in an illustrative example, in the TESR 125, the DTS 120 may supply a heat flow in one direction through the p-silicon solid wafer 155 and in an opposite direction through the n-silicon solid wafer 165. As such, for example, a super high electric current may be induced to flow around the TESR 125 by aggregating the electric current induced at each of the CGC 145 in the TESR 125.

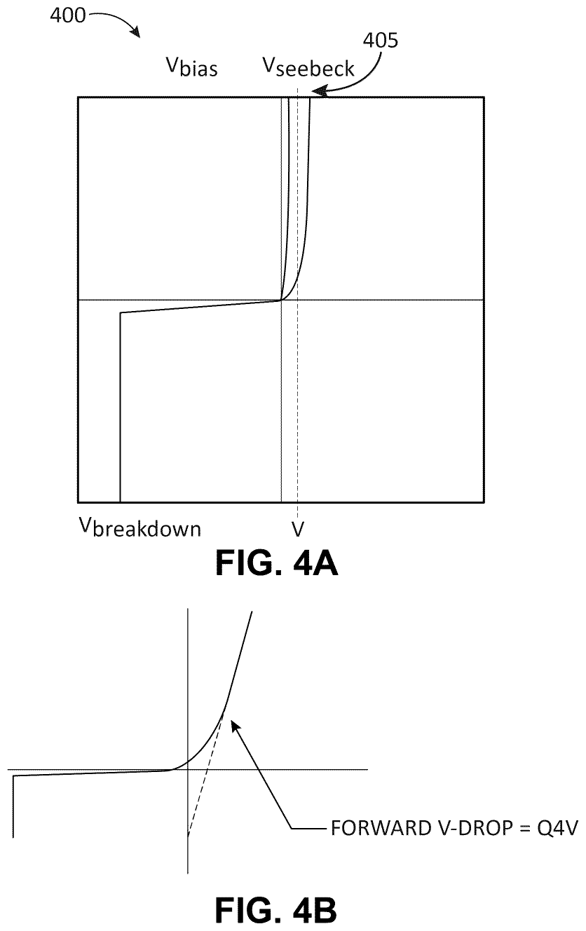

FIG. 4A and FIG. 4B show exemplary transfer characteristics of a forward bias voltage 400 of an exemplary p-type solid wafer as described with reference to FIGS. 3A-3C. As shown in FIG. 4A, a voltage applied between the entrance layer 305 and the exit layer 310 is represented by a horizontal axis. A current corresponding to the applied voltage is represented by a vertical axis. As shown, when a negative voltage above a breakdown voltage (V_{breakdown}) is applied between the entrance layer 305 and the exit layer 310, the p-silicon solid wafer 155 is not conducting so that no current is flowing at the p-silicon solid wafer 155. For example, V_{breakdown} may be −60V to −800V. When the applied voltage increases to a positive voltage, above the forward bias voltage 400 (V_{bias}), a current begins to flow.

In some implementations, the TESR 125 may induce a current with a voltage applied between the entrance layer 305 and the exit layer 310 at around a Seebeck voltage (V_{Seebeck}). As shown, V_{bias}<V_{Seebeck}. For example, V_{bias} may be reduced to close to zero (e.g., less than 0.02V). As such, the CGC 145 that includes a p-silicon solid wafer 155 and a n-silicon solid wafer 165 may include near-zero resistance when a temperature differential is introduced in the forward direction such that an electric current is induced by the CGC 145. In some implementations, when multiple CGCs 145 are combined to form the TESR 125 so that each CGC 145 may feed the induced electric current to an adjacent CGC 145, the TESR 125 formed may become superconducting. Some exemplary embodiments of a high efficiency conversion of heat energy to electrical energy using a ring of metallic components are discussed in the Inventor's own U.S. patent application Ser. No. 11/259,922, titled “Solid state thermoelectric power converter,” filed by Jon Murray Schroeder, et al., on Oct. 28, 2005, issued as U.S. Pat. No. 8,101,846. The foregoing application is entirely incorporated herein by reference.

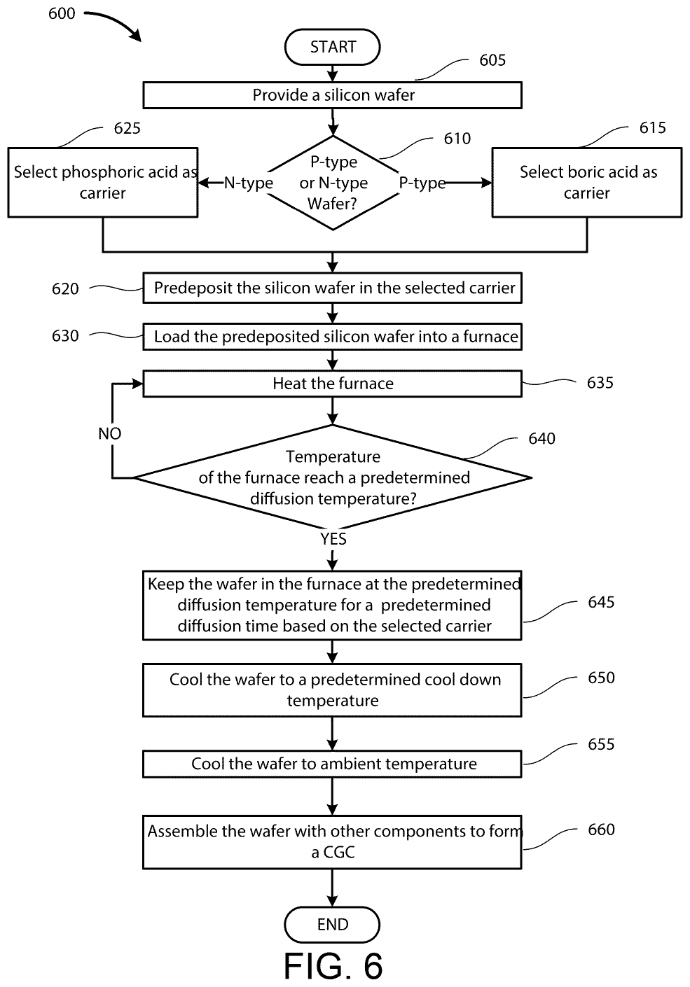

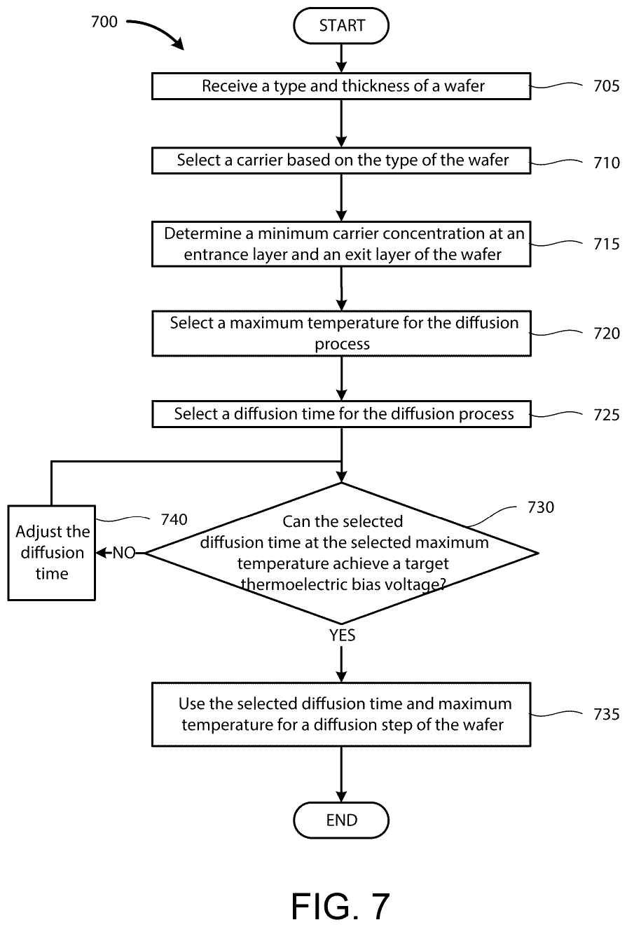

In some examples, V_{bias} may be controlled by controlling a carrier concentration at the entrance layer 305 and the exit layer 310. In various implementations, carriers may be introduced to the entrance layer 305 and the exit layer 310 using a diffusion step as described with reference to FIGS. 6-7. As an illustrative example without limitation, V_{bias} of the p-silicon solid wafer 155 may be reduced by the diffusion step as shown by an arrow 405.

In various implementations, the concentration and depth (e.g., X₁, X₂, X₁ₙ, X₂ₙ) may be determined by parameters applied to a solid wafer at the diffusion step. In some examples, a carrier (e.g., impurities) for doping may be selected. Based on the carrier selected, a manufacturing process may include parameters (e.g., including a deposition temperature, a diffusion time for the carriers at the diffusion step) to achieve a target forward bias voltage at the entrance layer 305 and the exit layer 310, for example.

In some implementations, power generated by the SSG 105 may be depending on a steepness (e.g., from zero) of the V_{bias}. For example, the steepness of V_{bias} may change as a function of a concentration distribution of n-+N and p-+P carriers produced by the +N and +P diffusion, a temperature differential between silicon sides, and ring current.

In some examples, a cross-over voltage where the current crosses the TESR 125's 20-mV output may be determined by heating and/or cooling the TESR 125. For example, if a higher temperature differential is produced across each solid wafer (e.g., the n-silicon solid wafer 165 and the p-silicon solid wafer 155) at the TESR 125, each of the CGC 145 may be configured to produce higher voltage.

For example, the V_{bias} in FIG. 4A may be a linear increasing between 0V and 0.02V. In some implementations, each CGC 145 may be tested at an open circuit at 0.02V. For example, a 30 Amps current may be driven at the CGC 145 being tested. For example, a forward voltage of the CGC 145 under testing may be observed. For example, any CGC 145 that is not within a predetermined steepness threshold (e.g., not being linear enough between 0V to 0.02V, showing a hump/non-linearity) may be disqualified from being installed in to the TESR 125.

In some implementations, the impurities (e.g., the P+ and/or N+ impurities) may make ohmic contact with wafers (e.g., the p-type substrate 315 and/or the n-type substrate 330). For example, the resulting wafers may include a forward bias voltage that start at 0V at 0 Amp and increases linearly towards the Seebeck voltage. For example, the linearly increasing forward bias voltage wafers may advantageously eliminate a 0.4V hump of a normal diffused silicon diode. For example, the wafers may produce a current with high multiples (e.g., 120 times using a 60-coupons TESR 125) due to small Seebeck voltage.

For example, a typical silicon diode may include a forward voltage resistance of 0.4 V forward voltage drop. In some implementations, when heated and cooled N+N- and P+P-silicon materials (e.g., by laying along with Sun-heated and ambient air cooling of silicon junctions), the forward voltage resistance may be reduced. In some examples, a current curving upward from zero for a couple in a ring of heated and cooled N+N- and P+P-silicon materials (e.g., the TESR 125) that limited current increasing due to heat flow may result as shown in FIG. 4B.

FIG. 5 shows exemplary deposition temperature selections based on solid solubility of a selected carrier. For example, p-type impurity may be diffused into both front and back surfaces (e.g., the entrance layer 305 and the exit layer 310) of a p-silicon solid wafer 155 to significantly reduce a normally induced 0.4V forward bias voltage. For example, the n-type impurity may be diffused into both front and back surfaces (e.g., the entrance layer 320 and the exit layer 325) of a n-silicon solid wafer 165 to significantly reduce a normally induced 0.4V forward bias voltage.

In some implementations, a solid-state diffusion process may be used to form diffused layers of impurities in the p-silicon solid wafer 155 and the n-silicon solid wafer 165. For example, the diffused layer may be formed in the p-silicon solid wafer 155 and the n-silicon solid wafer 165 in a two step process. In a pre-deposition step, impurities may, for example, be introduced to a semiconductor wafer to a depth of a few microns (e.g., less than 10 microns, less than 20 microns). Once the impurities are introduced, in a diffusion step, the impurities may be forced to diffused deeper into the wafer to provide a suitable concentration distribution (e.g., the Cₘᵢₙ₁, Cₘᵢₙ₂, C_{min1_n}, C_{min2_n} as described with reference to FIGS. 3A-3E), for example.

In some implementations, the predeposition step may be performed by placing the wafer in a carrier acid (e.g., boric acid, phosphoric acid) for a predetermined time. Next, for example, in the diffusion step, carrier deposited wafer may be placed in a diffusion furnace. For example, boron doped wafers may be diffused in a p-type furnace. For example, phosphorus doped wafers may be diffused in a separate n-type furnace. In some examples, using separate p-type and n-type furnaces may advantageously improve reliability of the resulting p-silicon solid wafer 155 and n-silicon solid wafer 165.

In some implementations, the diffusion furnace may be configured to heat the carrier deposited wafer to a first predetermined temperature T₁ for a first predetermined time t₁ (e.g., 10 minutes). For example, the first predetermined temperature may be between 800° C. to 1200° C. Next, in some implementations, the carrier deposited wafer may be allowed to cool to a second predetermined temperature T₂ for a second predetermined time t₂ in the diffusion furnace.

As an illustrative example, at a present process, boron may be selected to diffuse into the p-silicon solid wafer 155. For example, a range of depth of X, as shown in the graph 500, may be determined based on a minimum concentration required to reduce the forward bias voltage of the p-silicon solid wafer 155 to a near zero V_{bais} as described with reference to FIG. 4A. As shown in a solubility graph 500, solid solubility of the p-type boron (B) with respect to temperature is shown. In this example, at T_{B}, boron may include a solid solubility that allows it to diffuse to the predetermined range of depth X. Accordingly, for example, the first predetermined temperature is determined to be T_{B}. Similarly, for the n-type furnace for diffusing phosphorus to the n-silicon solid wafer 165, a temperature T_{P} may be selected.

FIG. 6 is a flowchart illustrating an exemplary CGC manufacturing method 600. For example, the method 600 may be performed to produce the CGC 145. In this example, the method begins when a silicon wafer is provided in step 605. For example, the silicon wafer may be first having oxide layer removed by dipping into a Hydrofluoric acid for three minutes. Next, in a decision point 610, it is determined whether the silicon wafer is a p-type or an n-type wafer. If it is a p-type wafer, boric acid is selected as carrier in step 615. In step 620, the wafer is predeposited in the selected carrier. For example, the silicon wafer may be dipped into ant poison to create a first deposited layer for a p-type wafer.

If the wafer is an n-type wafer, in step 625, phosphoric acid is selected as carrier, and the step 620 is repeated. For example, phosphoric acid may be used to deposit the first carrier layer for a n-type wafer.

In step 630, the predeposited wafer is loaded into a furnace. For example, a n-type wafer may be loaded to an n-type furnace. A p-type wafer may be loaded to a p-type furnace, for example. After the wafer is loaded, the furnace is heated in step 635.

In a decision point 640, it is determined whether the temperature of the furnace reached a predetermined diffusion temperature. For example, for boron as the carrier, the predetermined temperature may be 1200° C. as described with reference to FIG. 5.

In step 645, the wafer in the furnace is kept at the predetermined diffusion temperature for a predetermined diffusion time based on the selected carrier. Next, the wafer is cooled to a predetermined cool down temperature (e.g., 500° C.) in step 650. After the wafer is cooled to a predetermined cool down temperature, the wafer is cooled to an ambient temperature in step 655. For example, a furnace door may be open at this step. In step 660, the wafer is assembled with other components to form a CGC. For example, the wafers may be diced into ¾″ by ¾″ dies. For example, the dies (e.g., edges while leaving the contact area unpainted) may be painted with colors to identify a type (n-type or p-type). For example, the n-type die and the p-type die may be bonded together with the cold metal fin 150 and the hot metal fin 160 to form a CGC 145.

In some implementations, a high-temperature tolerant epoxy (e.g., a silver epoxy) may be applied to the surface of the CGC (e.g., to bond a fin to the CGC). For example, the high temperature tolerant epoxy may withstand a temperature of more than 480° C. By way of example and not limitation, some implementation may use LOCTITE ABLESTIK (available from Henkel Corporation, Culver City, CA).

FIG. 7 is a flowchart illustrating an exemplary method 700 for selecting parameters for manufacturing a forward bias regulated semiconductor. For example, the parameters may be set based on at least partially the solid solubility of a selected carrier as described with reference to FIG. 5.

The method 700 begins when a type and thickness of a wafer is received in step 705. For example, a type and thickness of a silicon wafer is provided. Next, in step 710, a carrier based on the type of the wafer is selected. For example, boron is selected for a p-type wafer. For example, phosphorus is selected for an n-type wafer.

In step 715, a minimum carrier concentration at a forward layer and an entrance layer of the wafer is determined. For example, the minimum carrier concentration may be determined based on empirical experimental results of the selected carrier. A maximum temperature (e.g., T₁ as described with reference to FIG. 5) for the diffusion process is selected in step 720. Next, in step 725, a diffusion time for the diffusion process is selected.

In a decision point 730, it is determined whether the selected diffusion time at the selected maximum temperature can achieve a target thermoelectric bias voltage. For example, the target thermoelectric bias voltage may be determined by historical data. If it is determined that the selected diffusion time at the selected maximum temperature can achieve a target thermoelectric bias voltage, in step 735, the selected diffusion time and maximum temperature for a diffusion step of the wafer is used, and the method 700 ends.

If it is determined that the selected diffusion time at the selected maximum temperature cannot achieve a target thermoelectric bias voltage, in step 740, the selected diffusion time is adjusted and the decision point 730 is repeated.

In some implementations, a wafer (e.g., a silicon wafer) may be de-oxidized prior to diffusion. For example, a silicon wafer may be de-oxidized using acid (e.g., acid-dipped) to remove silicon-oxide prior to diffusion. For example, hydrofluoric acid may be used (e.g., 8-10% concentrate diluted 10 parts deionized water to 1 part acid solution) to acid-dip the silicon wafer.

FIG. 8 depicts an exemplary solar energy transportation system (SETS) in an illustrative use-case scenario. In this example, a SETS 800 includes a SSG 105. The SSG 105 is operably coupled to a solid state generation store (SSGS 122). The SSGS 122 includes gen-stones 810. For example, the SSGS 122 may be 70% filled with multiple of the gen-stones 810. For example, the SSGS 122 may be 75% filled with multiple of the gen-stones 810. For example, the SSGS 122 may be 85% filled with multiple of the gen-stones 810. The gen-stones 810 may include insulated hot bauxite alumina. In some embodiments, the SETS 800 may be a 20-foot on sea structure the gen-stones 810 to supply two or more SSGs 105. For example, the SETS 800 may supply 1-MW-month selectively supplied to a power grid.

In some implementations, the gen-stones 810 may, for example, be graded by size. For example, the gen-stones 810 may include a distribution of volumes (e.g., pea-sized, golf-ball sized). For example, the gen-stones 810 may have a limited amount of dust (e.g., less than 1%, less than 5%, less than 10%). For example, the distribution of volumes and/or the maximum permitted amount of dust (e.g., by volume) may be selected to achieve a percentage fill of a volume. For example, the gen-stones 810 may be selected and mixed with varying sizes (e.g., maximum outer radius, individual volume) to achieve a predetermined percentage fill by volume (e.g., of the SSGS 122, as discussed above). The gen-stones 810 may, for example, be selected and/or spatially distributed such that voids (e.g., air gaps) are spatially distributed throughout the gen-stone-filled volume of the SSGS 122. In some implementations, for example, the fill may be selected such that a flow rate (e.g., volume per unit time) of fluid (e.g., air, water, nitrogen gas) through the voids may be driven by a pressure not to exceed a predetermined maximum driving pressure. In some implementations, by way of example and not limitation, the predetermined maximum driving pressure may be 20.7 kPa (kilopascals) (3 pounds per square inch).

As shown in this example, the SSGS 122 is coupled to a solar energy collector 815. For example, the solar energy collector 815 may supply hot air to heat the gen-stones 810. For example, the gen-stones 810 may store the thermal energy received. In this example, the SSGS 122 may circulate cooled air back to the solar energy collector 815 to be reheated.

In this example, the SSGS 122 also includes a hi-nickel heater 820. The hi-nickel heater 820 may be powered by an external electricity supply. For example, the external electricity supply may be generated by wind power. In some implementations, the SETS 800 may use excess electricity generated by the SSG 105 to power the hi-nickel heater 820 and may use the gen-stones 810 (e.g., alumina bauxite) for heat storage for future electricity generation. In some implementations, the SSGS 122 may be heated using methane burned from a low pressure gas well. As shown, the SSGS 122 may circulate heated air through the CGC 145 of the SSG 105. For example, the used air may be exhausted back to the SSGS 122 for reheating.

In some embodiments, the SETS 800 may be distributed at locations along a power grid to be ready for quick switching to supply supplementary power to the power grid. For example, during times with less electricity demand (e.g., at 12 am-6 am), the SETS 800 may store the excess power in the SSGS 122. For example, in peak demand times, the SETS 800 may inject supplementary power to the power grid. In some implementations, the SETS 800 may include a control system to automatically control and transport the SSGS 122 from one location to another based on power demand forecast.

In some examples, in a three-phased power system, power at a top and a bottom of each phase are not delivered to customers. In some implementations, the SETS 800 may extract the undelivered power and store the extracted energy in the SSGS 122. For example, 10% of power at the top and 10% of power at the bottom of each phase may be captured. In some implementations, when power demand is high, the SETS 800 may convert the stored power to the market to meet the excess power demand. For example, the SETS 800 may advantageously balance power supply and demand to reduce costs.

FIG. 9 depicts an exemplary freshwater production system (FPS 900) in an illustrative use-case scenario. In this example, the FPS 900 includes the SSG 105. For example, the SSG 105 may generate cold air when an electric current is supplied through the TESR 125. As shown, the generated cold air may be supplied to a reservoir 905 of salt water (e.g., sea water). For example, the salt water may be frozen by the cold air. In some examples, salt residue on the freshwater ice may be rinsed off so that the freshwater ice may be extracted. Various embodiments and applications of the FPS 900 are described with reference to FIGS. 33-35 of Inventor's previously filed U.S. patent application Ser. No. 11/517,882, titled “Thermoelectric device with make-before-break high frequency converter,” filed by Jon Murray Schroeder, et al., on Sep. 8, 2006, issued as U.S. Pat. No. 8,183,456. The foregoing application is entirely incorporated herein by reference. For example, the freshwater ice may be melted to use the melted water for irrigation and to drink.

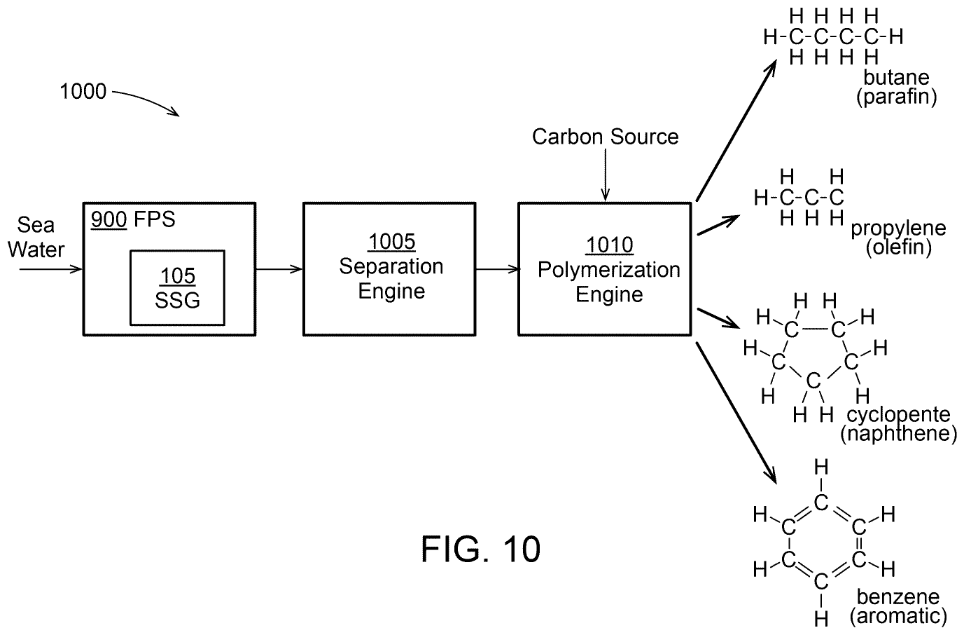

FIG. 10 depicts an exemplary carbon neutral fuel synthesizing system (CNFSS 1000) in an illustrative use-case scenario. In this example, the CNFSS 1000 includes the FPS 900 to receive sea water input. As discussed above, the FPS 900 includes a SSG 105 to generate freshwater. The CNFSS 1000 includes a separation engine 1005. In this example, the separation engine 1005 receives the freshwater to produce hydrogen to supply a polymerization engine 1010.

The polymerization engine 1010 receives also a carbon source to generate various hydrocarbon compounds. For example, the polymerization engine 1010 may produce butane, olefin, benzene, cyclopentane. In some examples, the generated hydrocarbon compounds may be used to produce jet fuel.

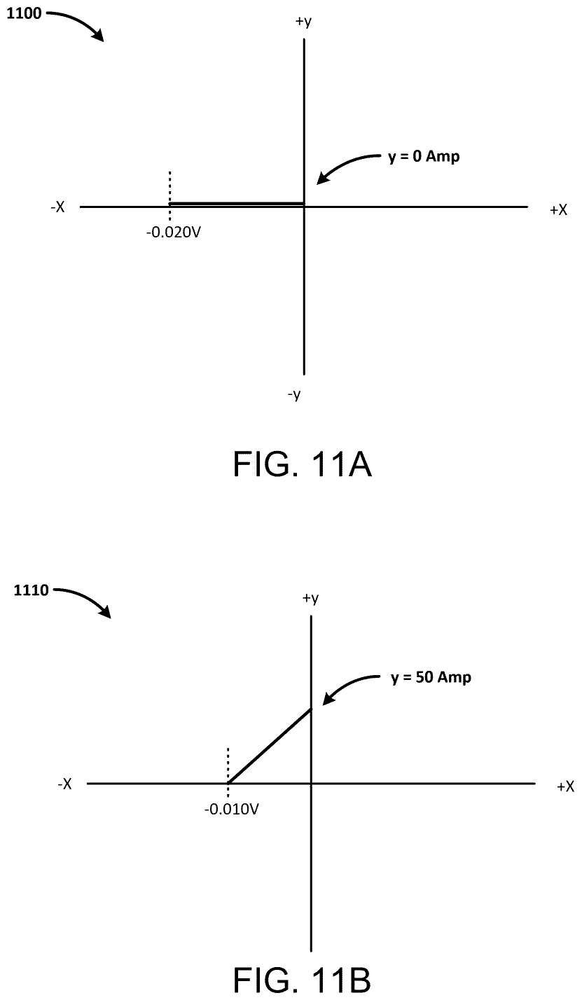

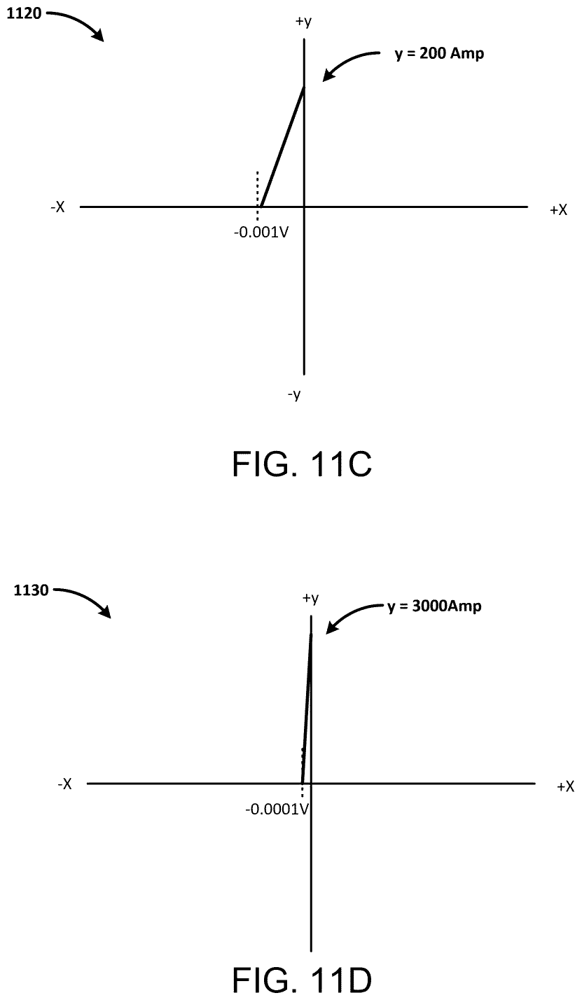

In some embodiments, the CGC 145 of a TESR 125 may vary in resistance. For example, the CGC 145 may balance each other out in resistance. For example, when a high current is flowing in the TESR 125, the CGC 145 having, for example, a lower resistance (e.g., FIG. 11D) may compensate for CGCs having a higher resistance (e.g., FIG. 11C). FIG. 11A, FIG. 11B, FIG. 11C, and FIG. 11D depict exemplary progress of reducing voltage in a highly conducting current generation coupon (CGC). In these figures, the x-axis depicts voltage and the y-axis depicts amperage. The relationship between voltage, amperage, and resistance may, for example, be governed by Ohm's Law (V=I*R, which can be written as R=V/I), where V=voltage, I=current, and R=resistance.

In an example method of testing CGCs, electrical energy may be applied (e.g., by applying current to generate a voltage in the CGC), illustrative test results have been obtained. In some implementations, due to the Seebeck effect, the voltage in a CGC in an open circuit (no current) may, for example, be about −0.020V, as shown in plot 1100 of FIG. 11A. As shown in plot 1110 of FIG. 11B, a CGC 1110 may include a low resistance at −0.01V. For example, when the voltage is reduced to −0.010V in the CGC, and the forward bias voltage is met, a current of 50A may be produced. As shown in plot 1120 of FIG. 11C, the resistance of CGC may be further reduced when the voltage is reduced to −0.001V. For example, when a forward bias voltage is met, a current of 200 A may be produced. As shown in plot 1130 of FIG. 11D, a CGC 1130 may include a still further reduced resistance at −0.0001X. For example, when a forward bias is met in the CGC, a current of 3000 A may be produced. In some implementations, the CGC 1130 may include an effective resistance of R=V/I<0.0001/3000=0.00000003 Ω. For example, a CGC with such low resistance may, in some cases, be considered super conducting.

The CGCs may, for example, be connected in a ring as disclosed at least with reference to TESR 125. Heat may, for example, be used to generate current in the ring. As the voltage decreases, the current may, for example, increase to exceed 1000 A. For example, the current may exceed 3000 A.

A switching device coupled to the ring (e.g., power switch 135) may, for example, include one or more variable resistor modules. The variable resistor module(s) may, for example, be operated to maintain a current within a desired limit (e.g., for safety, such as <3000 A, such as <1000 A). The switch(es) may, for example, be operated to reverse the current direction in the CGC sequence (e.g., the TESC 125, such as a ‘ring’ of CGCs). Without being bound to a particular theory, some embodiments may utilize the Seebeck effect, upon application of thermal energy, using CGCs as disclosed herein to approach zero resistance in the CGCs as the forward bias voltage is reduced. The current may increase (e.g., >1000 A), which may be used to drive a transformer (e.g., as disclosed at least with reference to FIG. 1).

For example, in a test, current was applied to CGCs in a test setup in which current was applied to drive voltage in a CGC. As current was increased to up to 1000 A, the voltage was reduced according to the progression depicted at least in FIGS. 11A-11C, demonstrating reduced voltage. The CGCs were created according to the method as disclosed at least with reference to FIG. 6. The CGCs were determined to have a distance X₁ₙ of approximately at least 10 microns. The CGCs had a depth X₂ₙ of approximately at least 10 microns. The CGCs had an overall thickness of at least about 0.05 inches. The CGCs n-type had a Cmin_2n determined to be at least about 10 times higher than Cmax_n. The CGCs n-type had a Cmin_n1 determined to be about 10 times higher than Cmax_n. The CGCs p-type had a Cmin2 determined to be at least about 10 times higher than Cmax. The CGCs p-type had a Cmin1 determined to be about 10 times higher than Cmax. In the test, the current was limited to 1000 A due to testing equipment limitations; however, no physical limit of the CGC was reached. The current was confirmed by measuring the reduction in voltage.

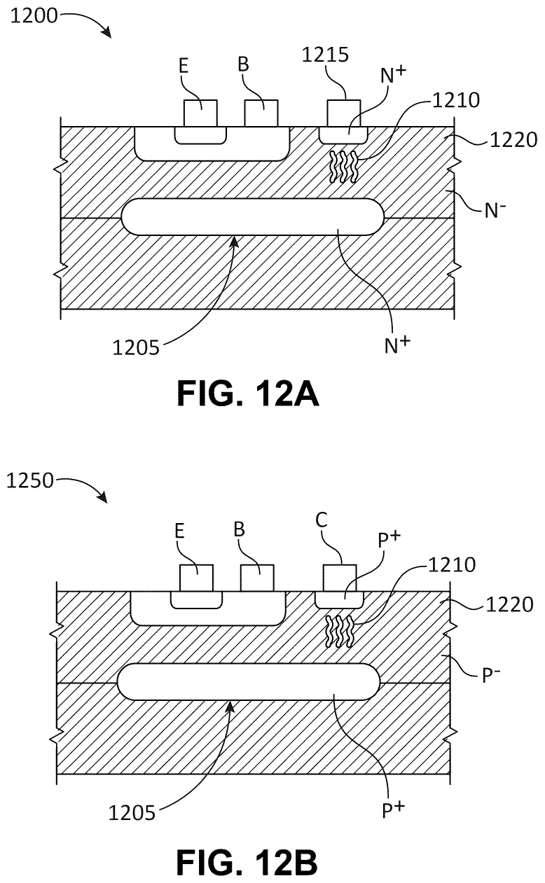

FIG. 12A and FIG. 12B depict an exemplary structure of a highly conducting semiconductor wafer (HCSW). As shown in FIG. 12A, a HCSW 1200 (e.g., a silicon integrated circuit, a semiconductor integrated circuit) includes a buried collector region 1205. For example, the HCSW 1200 may be an N-type silicon integrated circuit. As described with reference to FIG. 12B, a HCSW 1250 may be a P type silicon integrated circuit. For example, the HCSW 1200 may include a silicon doped wafer. For example, the buried collector region 1205 may operate to reduce a collector resistance of the HCSW 1200.

In this example, the HCSW 1200 includes an ohmic contact 1210 disposed to connect the buried collector region 1205 to a (top-side) collector contact 1215. As shown, the ohmic contact 1210 may be disposed in an epitaxial layer 1220. For example, the epitaxial layer 1220 may include a lightly doped N-layer (P-in the HCSW 1250). In some implementations, the ohmic contact 1210 may include a low or very low (e.g., non-measurable) resistance in a forward current direction as a collector current is increased above a predetermined threshold. (as described with reference to FIGS. 11A-D).

In various implementations, the ohmic contact 1210 may be created by performing a high-concertation pre-deposition (e.g., >E+4 carriers, higher than the substrate resistivity) on a collector imaged silicon surface of an otherwise isolated integrated electrical circuit. In some implementations, by pre-depositing a same type of impurities into lightly doped silicon P- or N-type wafers, respectively, before forming an isolated integrated circuit (e.g., the HCSW 1200).

The HCSW 1200 may include a reduced collector resistance when heat flows in the HCSW, in some implementations. As such, for example, a superconductivity condition (Tc) of the CGC 1200 may be created without a need for using cryogenics to cool the CGC 1200. For example, using the CGC 1200 ring as described with reference to FIGS. 12A-B, Tc may be achieved at new critical temperatures between +50 C and +250 C.

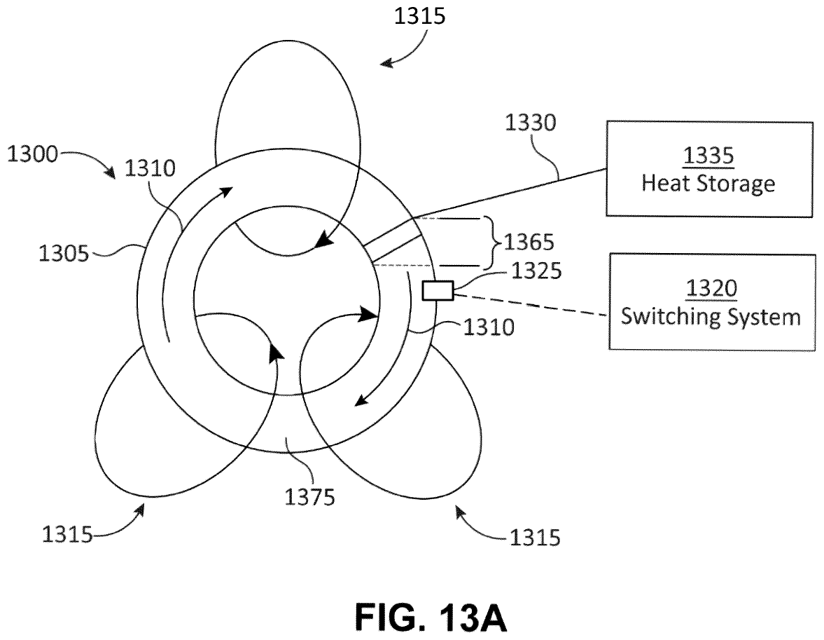

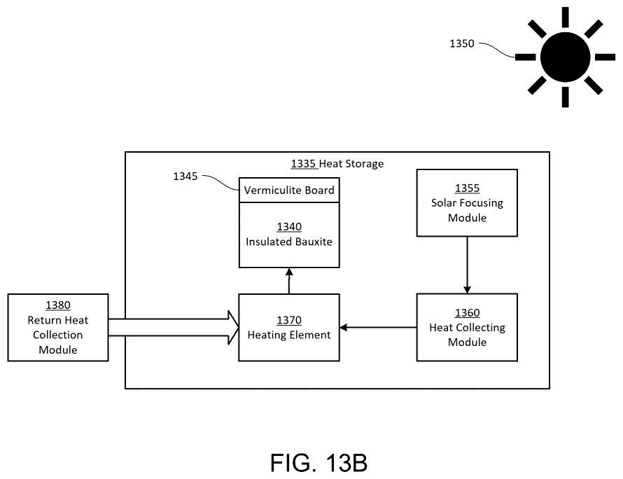

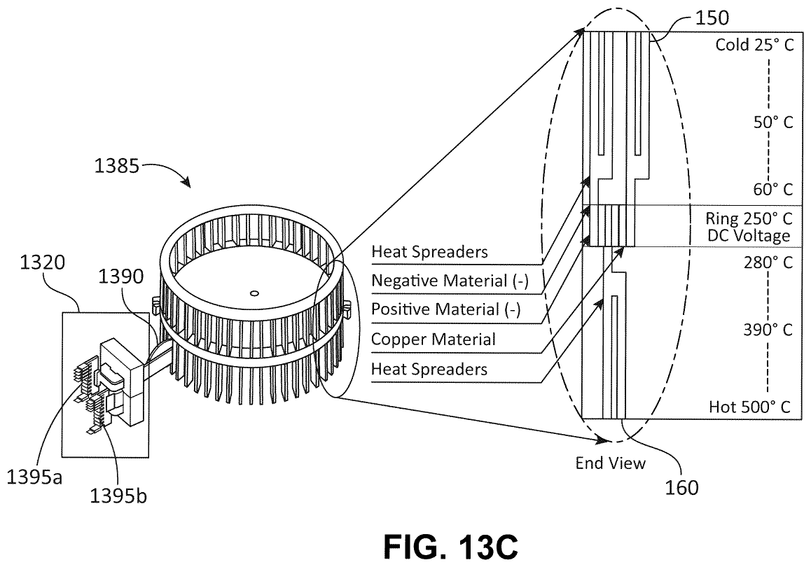

FIG. 13A, FIG. 13B, and FIG. 13C are block diagrams showing an exemplary thermal energy generation and storage system (TEGASS). As shown in FIG. 13A, a TEGASS 1300 includes a shorted ring 1305. Arrows 1310 shows how current flow in the shorted ring 1305 at an example time. For example, the current flowing direction as shown by the arrows 1310 may create a magnetic field 1315 for, for example, as long as current is caused to flow in the shorted ring 1305.

In some implementations, the magnetic field 1315 may penetrate through a center opening of the shorted ring 1305. For example, the magnetic field 1315 may be (e.g., evenly) distributed around the shorted ring 1305 (e.g., according to Faraday's law of induction where the magnetic field 1315 is the electric field along the closed loop of the shorted ring 1305, and the magnetic field through, in and around the opening of the shorted ring 1305).

In some examples, to produce AC electricity, a changing magnetic field called a magnetic flux is required. As shown, the TEGASS 1300 includes a switching system 1320. For example, the switching system 1320 may include an up converter. For example, the switching system 1320 may be installed across a break 1325 in the shorted ring 1305. In some implementations, the break 1325 may include a piece of high temperature mica insulating material. For example, the break 1325 may create a parting in the shorted ring 1305. In some examples, the switching system 1320 may be inserted at the break 1325.

As shown, the shorted ring 1305 includes coupons of alternating semiconductor junction (ASJ 1365) inserted within a conducting mass 1375 (e.g., a copper material). For example, the ASJ 1365 may include an N-type junction in connection with a P-type junction as described with reference to FIGS. 12A-B. For example, the ASJ 1365 may generate a current flow caused by heat flow through each of the ASJ 1365 received from a heat storage 1335.

As shown in FIG. 13B, the heat storage 1335 may deliver thermal energy (e.g., heat) derived from stored heat in insulated bauxite 1340. As shown, thermal energy may be transferred by a heat transfer module 1330. For example, the heat transfer module 1330 may include an air circulation system flowing through the insulated bauxite 1340 and to the hot metal fins of the ASJ 1365. In some implementations, the insulated bauxite 1340 may be insulated by a insulation layer 1345 contained in a (e.g., 20-ft) sea freight container. In some implementations, the heat storage 1335 may receive the heat from a sun 1350. For example, the stored heat may be configured to operate the TEGASS 1300.

In this example, the heat storage 1335 may include a solar focusing module (SFM 1355). For example, the SFM 1355 may focus a heat from the sun to a heat collecting module (HCM 1360). For example, the HCM 1360 may include a long piece of stainless steel exhaust piping. For example, the HCM 1360 may be configured to receive forced air circulating the heated air through the ASJ 1365 bauxite heat store. In some examples, the ASJ 1365 may include a half-life of a month or more.

In this example, the heat storage 1335 includes a heating element 1370. For example, the heating element 1370 may receive, as shown in this example, at least part of an excess energy (e.g., electricity) not needed by an output load (e.g., the power grid 115) from an excess energy collection module (EECM 1380). For example, the heating element 1370 may heat up the insulated bauxite 1340 (e.g., for use later).

In some implementations, current in the shorted ring 1305 may be maintained by alternating heat flowing through opposite sides of the ASJ 1365. For example, the alternate heat flow may each add voltage around the shorted ring 1305 as long as heat flows through a series of the ASJ 1365 of the shorted ring 1305.

In some embodiments, the generated current may persist in one direction of the shorted ring 1305. In some examples, no decrease in ring current may be observed over a thousand-hour period. For example, the insulated bauxite 1340 may have a lifetime of 99-years in grid service. As described with reference to FIGS. 1-4B, the ASJ 1365 may generate, for example, a superconducting effect when a thermal differential is applied (e.g., between the cold metal fin 150 and the hot metal fin 160). In some embodiments, the superconducting effect may allow a current through flowing through the conducting mass 1375 with the ASJ 1365 (e.g., silicon chips) held at elevated, differential temperatures.

As an illustrative example, the TEGASS 1300 may operate in temperature between +50C and +250C. In some implementations, the shorted ring 1305 may receive forced ambient air a cooling agent. In some examples, the ASJ 1365 may include an N-type silicon junction in connection with a P-type silicon junction. In some embodiments, the ASJ 1365 may use other materials. For example, the ASJ 1365 may include Bismuth Telluride (BiTe) thermal junctions. For example, the BiTe junctions may provide a low melting point (e.g., at 271.4C). For example, silicon junctions may advantageously operate for long period of time (e.g., more than 100 years) at high temperatures (e.g., at 1,200C or higher) without melting.

In various implementations, a solid state electricity generator (SSEG) (e.g., the TEGASS 1300) may include a ring of thermal junctions (e.g., the ASJ 1365). For example, the SSEG may apply a temperature differential to the thermal junctions by using heated air harvested from focused, stored sunshine as a heating source, and ambient air-cooling of silicon junctions for cooling. For example, the harvested thermal energy may be stored in a heat storage (e.g., the heat storage 1335). For example, when electricity is needed, the heat storage may be configured to transfer air through a secondary heat source (e.g., the insulated bauxite 1340) to the thermal junctions. In some examples, waste heat may return to the heat storage (e.g., the EECM 1380). Various embodiments may advantageously generate electricity for heat storage and supplying an electric grid.

In some examples, the TEGASS 1300 may generate a superconducting effect without use of cryogenics fluids for cooling of conductive materials. For example, the magnetic field 1315 trapped in the shorted ring 1305 (e.g., a superconducting ring) may efficiently store electrical energy.

As shown in FIG. 13C, a ring assembly and control circuit 1385 may include the shorted ring 1305. For example, the ring assembly and control circuit 1385 may include a ring of the ASJ 1365 (coupons) separated by a dielectric mica die 1390. For example, the dielectric mica die 1390 may connect, at either side, a voltage up-converter circuit configured to drive a primary current through a DC-to-DC up-converter system. Various embodiments of the ring assembly and control circuit 1385 are described in the inventors previous patent applications, U.S. patent application Ser. No. 13/374,129, titled “Solid state thermoelectric power converter,” filed on Dec. 13, 2011, by the same inventor of this application. This application incorporates the entire contents of the foregoing application(s) herein by reference.

In various implementations, the ring assembly and control circuit 1385 may include a shorted ring of coupons (e.g., the ASJ 1365). As shown in an end view in this example, a high current (with reduced resistance in the ring) may be achieved by adjusting the forward voltage, caused by heat flow from the hot metal fin 160 to the cold metal fin 150. In some examples, the current generated may be pushed across a zero-resistance silicon die. For example, with near zero forward resistance for the ring, the current flowing through coupons may be considered superconducting the closed ring of coupons of the ring assembly and control circuit 1385.

As shown, the ring assembly and control circuit 1385 is constructed from P-type and N-type wafers. The P-type and N-type wafers may be pre-surface deposited with a higher concentration of the same type of impurity as the wafer's type's impurity. For example, the P-type and N-type wafers may include structures as described with reference to previous figures (e.g., the p-silicon solid wafer 155, the n-silicon solid wafer 165, the HCSW 1200, the HCSW 1250).

In some examples, a copper material (e.g., the conducting mass 1375) may turn the bonded assembly of coupons into a very tight, high current superconducting ring. Various embodiments with a copper wedge may advantageously carry thousands Amperes of current.

In this example, the switching system 1320 includes multiple switches (e.g., a first switch 1395a and a second switch 1395b) connected to a primary winding of a high frequency transformer. For example, the power switch 135 may include the first switch 1395a and/or the second switch 1395b. For example, the power switch 135 may include one voltage up-converter circuit. In some embodiments, each of the first switch 139a and the second switch 139b may be connected to a up-converter circuit (e.g., a step-up transformer). For example, the up-converter circuits may be drive a primary current through a DC-to-DC up-converter system. In some implementations, the switching system 1320 may include a magnetic transformer configured to be switched in high frequency (e.g., at 100 kHz, 150 kHz, 180 kHz, around or above 200 kHz). For example, the ring assembly and control circuit 1385 may generate a high voltage output from a transformer secondary multi-turn winding of the switching system 1320 operating at high frequency.

In operation, the first switch 1395a and the second switch 1395b may induce energy into a secondary winding by switching at a high frequency. In some examples, the high frequency switching may induce a current flow at the shorted ring 1305 by the magnetic field 1315. As discussed with reference to FIGS. 11A-D, when current increases, the resistance in the shorted ring 1305 may reduce. In some examples, when the current is above a predetermined threshold, the shorted ring 1305 may become superconducting. For example, the switching system 1320 may advantageously generate a high voltage (e.g., 110 VAC, 240 VAC) and alternating (e.g., at 50-60 Hz.) output. In some examples the output may be rectified into a DC current output.

In some implementations, the switching system 1320 may include steering switches. For example, the switching system 1320 may include a Pulse-With Modulator (PWM) circuit configured to convert the output into a power output compatible to a power grid. For example, an output of the TEGASS 1300 may be processed by a grid transformer to power in-phase power the grid with a 240 VAC output, with an output capacity of up to one-Mega-Watt (MW).

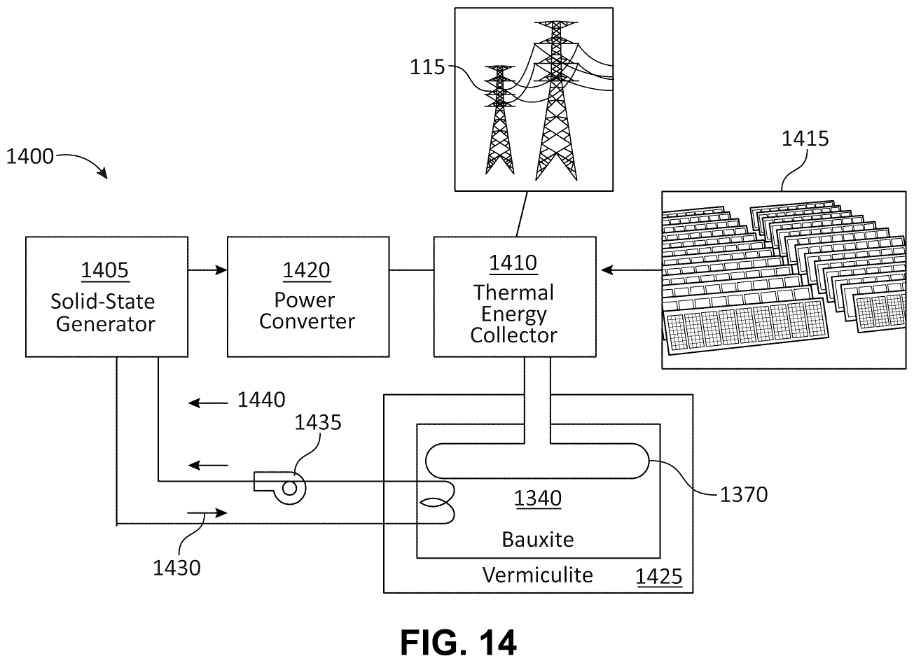

FIG. 14 depicts an exemplary solid-state generation system with an excess energy storage. For example, the SSGS 1400 may supply electrical energy to the power grid 115. In this example, a SSGS 1400 includes a solid-stage generator (SSG 1405) and a thermal energy collector 1410. For example, the thermal energy collector 1410 may collect solar energy from a solar farm 1415. The SSG 1405 may, for example, be the SSG 105. For example, the SSG 1405 may include the shorted ring 1305. For example, the SSGS 1400 may be configured to store surplus electricity produced by the SSG 1405 to be reused at a later time independent of heat produced by a thermal energy collector 1410.

In this example, the SSG 1405 may generate electricity to be processed by a power converter 1420. For example, the power converter 1420 may include the power switch 135 as described with reference to FIG. 1. For example, the power converter 1420 may convert generated power into AC compliant to the power grid 115.

The solar farm 1415 may, in the depicted example, aggregate thermal energy received from the solar farm 1415 and excess power from the power converter 1420 to power the heating element 1370. The heating element 1370 may power the insulated bauxite 1340. In some embodiments, other material with long half-life may be used. In this example, the insulated bauxite 1340 is insulated by a layer of vermiculite 1425. In some embodiments, other insulation material may be used.

In operation, for example, cold air 1430 may be heated up by transferring through the insulated bauxite 1340 using an air blower 1435. For example, the SSG 1405 may generate power using the temperature differential between hot air 1440 from the insulated bauxite 1340 and the cold air 1430.

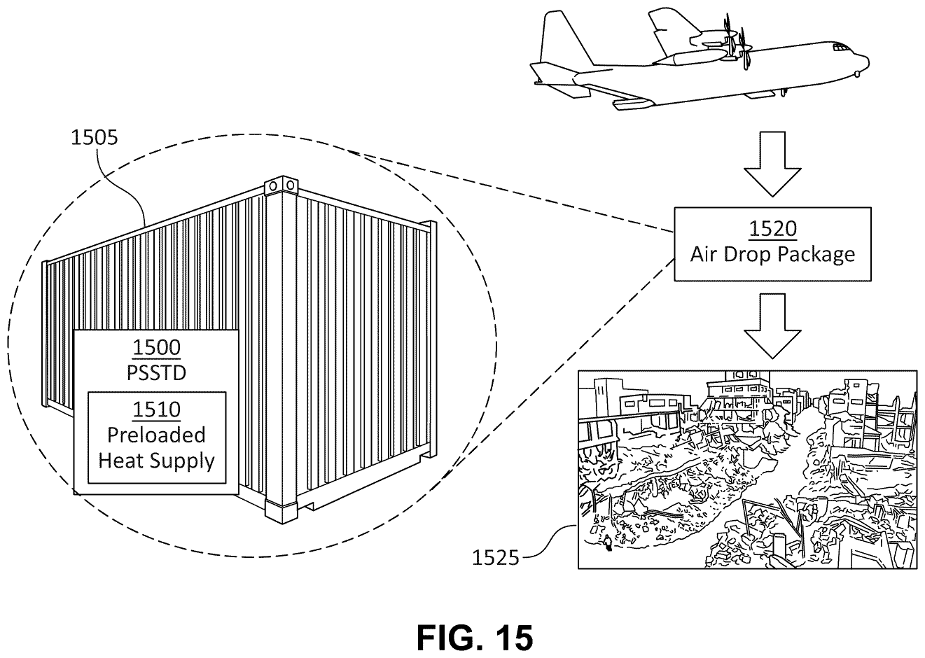

FIG. 15 shows an exemplary packaged solid-state superconducting thermoelectric device (PSSTD) in an illustrative use-case scenario. In this example, a PSSTD 1500 is packed within a sea freight container 1505 (e.g., a used 20-feet sea container). For example, the PSSTD 1500 may include the SSGS 1400. As shown, the PSSTD 1500 may include a preloaded heat supply 1510 (e.g., a 1-month supply of stored heat). For example, the PSSTD 1500 may use the preloaded heat supply 1510 to produce 1 MW worth of electricity for one month.

In this example, an air-drop package 1520 including the sea freight container 1505 and the PSSTD 1500 may be air-dropped (e.g., into a conflict zone, a disaster affected area). For example, the PSSTD 1500 may then be connected (e.g., through a transformer connection port) to a local grid section to supply electric power for regions with interrupted power 1525. Various embodiments may advantageously provide a pluggable solution to relive distress situations.

In some examples, the air-drop package 1520 may be transported to a distant grid location, for example, to power industry and/or to operate a vehicle (e.g., a truck, a train, a ship at sea). In some examples, the air-drop package 1520 may be transported to operate as a buffer for a wind farm (temporarily) without wind. In some examples, the air-drop package 1520 may be transported to assist in powering a turbo-fanjet aircraft engine using stored heat to make electricity driving an electric motor to drastically reduce aircraft's fuel burn. Various exemplary applications of the PSSTD 1500 and/or the SSGS 1400 are further described in a previously submitted patent application, published as U.S. 2010/0288322 A1, titled “Solar to Electric System,” co-invented by the inventor of this application. This application incorporates the entire contents of the foregoing application(s) herein by reference.

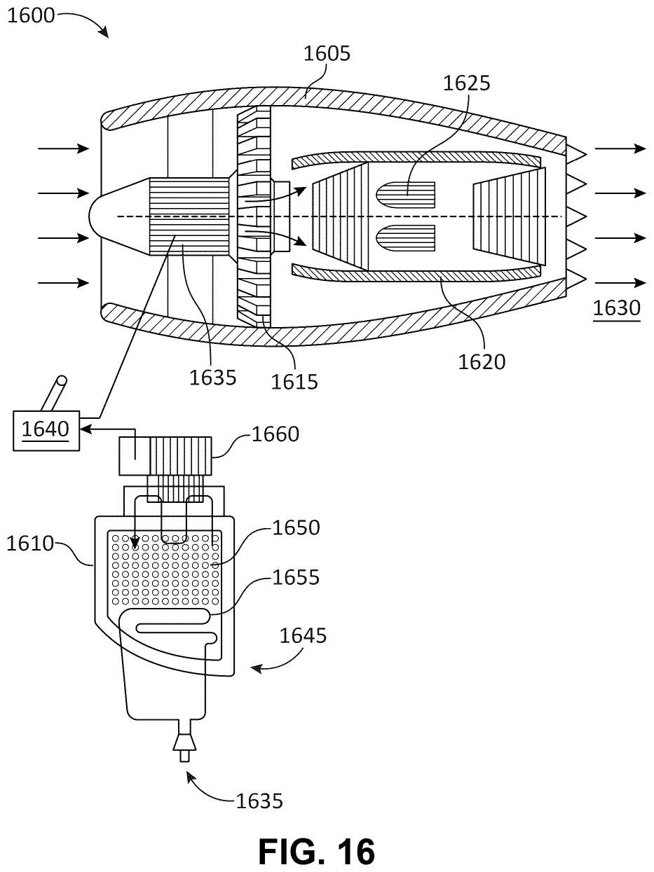

FIG. 16 depicts an exemplary hybrid jet engine 1600 coupled to an SSG. In this example, the exemplary hybrid jet engine 1600 includes an aircraft engine 1605 modified to operate with a SSG 1610.

The aircraft engine 1605 may include a forward-mounted fan 1615 driven by a low-pressure turbine 1620 and a burner chamber 1625. For example, the forward-mounted fan 1615 may direct ambient air through the low-pressure turbine 1620 and the burner chamber 1625. For example, fuel may be injected and combusted within the burner chamber 1625 to generate high-energy exhaust gases 1630, thereby producing mechanical energy for generating a forward thrust.

In the depicted example, the aircraft engine 1605 is operably coupled to an electric motor 1635 and a control 1640. For example, the electric motor 1635 may be configured to assist in rotational propulsion of the forward-mounted fan 1615 during selected phases of flight (e.g., takeoff, climb, cruise). In some examples, the electric motor 1635 may generate (e.g., auxiliary) power in response to reduced fuel availability and/or environmental operating constraints. The electric motor 1635 may be energized by the SSG 1610, in some implementations. For example, the control 1640 may control the power supplied from the SSG 1610 to the electric motor 1635.

The SSG 1610 includes a thermal-electric generation system 1645. For example, the thermal-electric generation system 1645 may include the TEGASS 1300 as described with reference to FIGS. 13A-C. Referring back to FIG. 16, the SSG 1610 includes high thermal mass components 1650 (e.g., hot rocks, the insulated bauxite 1340, thermally conductive rocks) and a heater 1655. The high thermal mass components 1650 may be heated by the heater 1655. In some implementations, the heater 1655 may receive excess electrical energy from an external source, a solar energy input, and/or energy recovered from engine waste heat. For example, the SSG 1610 may include a plurality of thermoelectric junctions (e.g., the ASJ 1365 having a plurality of coupons of alternating the HCSW 1200 and the HCSW 1250). In some examples, heat from the high thermal mass components 1650 may be conducted across the thermoelectric junctions to generate electricity for the electric motor 1635.

The generated electrical output may, for example, be regulated a switching system 1660. For example, the exemplary hybrid jet engine 1600 may include transformer coils. For example, the switching system 1660 may include pulse-width modulators and/or DC-to-AC inverters. In some embodiments, the control 1640 may be configured to dynamically regulate the electrical power supplied to the electric motor 1635 based on flight conditions, energy storage levels, and/or mission-specific profiles.

In operation, the exemplary hybrid jet engine 1600 may advantageously operate in a reduced fuel-burn mode when combustion-based propulsion is supplemented by power generated by the SSG 1610. In some implementations, the exemplary hybrid jet engine 1600 may operate with a reduced noise level and/or in low-emission mode (e.g., in energy demanding maneuvers like during taxiing or takeoff). In some examples, the SSG 1610 may be housed in a portable or air-droppable container and preloaded with stored heat for quick replacement and/or energy reloading.

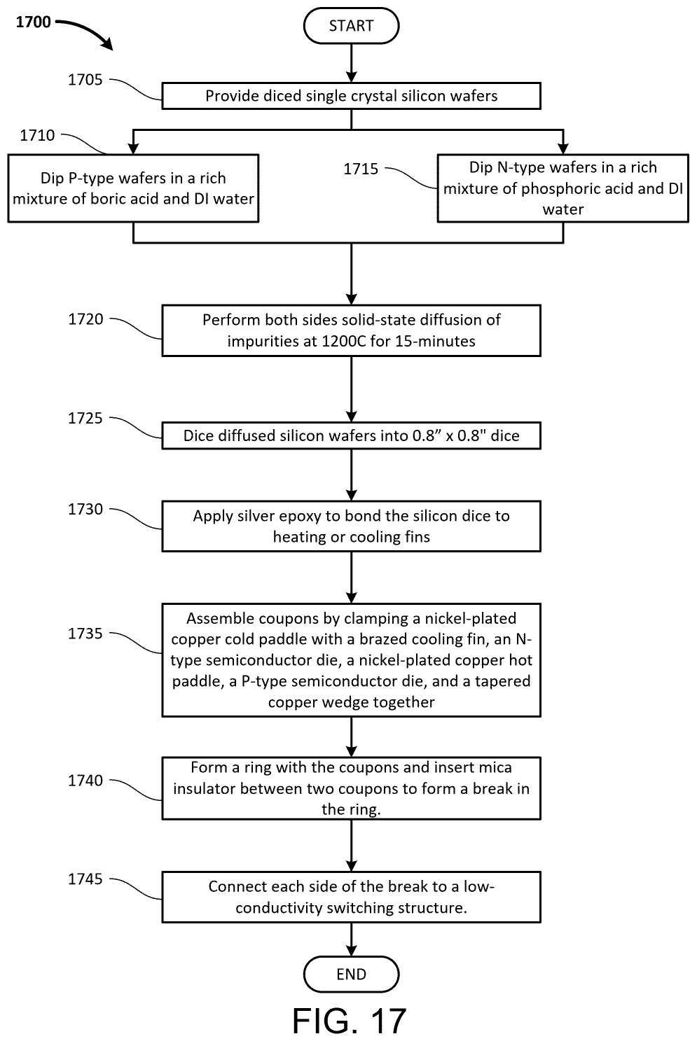

FIG. 17 is a flowchart showing an exemplary superconducting ring manufacturing method 1700. For example, the method 1700 may produce a silicon-copper ring made using coupons made from single crystal silicon wafers having a high temperature (e.g., between 60° C. to 150C) superconductivity. In this example, single crystal silicon wafers that are cut into dice are provided in step 1705. For example, the single crystal silicon wafers may be cut in either <100> or <111> orientation. For example, the single crystal silicon wafers may be cut to approximately 0.060 inch thick.

In step 1710, P-type wafers are dipped in a rich mixture of boric acid and DI water (e.g., for 2 minutes). In step 1715, alternatively, N-type wafers are dipped in a rich mixture of phosphoric acid and DI water. Next, in a diffusion furnace, perform both sides solid-state diffusion of impurities at 1200C for 15-minutes in step 1720. For example, the wafers are allowed to air-cool.

In step 1725, diffused silicon wafers are diced into 0.8″×0.8″ dice (e.g., by a scribe, a diamond saw). Silver epoxy are applied to bond the silicon dice to heating or cooling fins in step 1730. For example, the silver epoxy may add <0.00001-Ohm-cm of resistance.

Coupons are, in step 1735, assembled by clamping a nickel-plated copper cold paddle with a brazed cooling fin, an N-type semiconductor die, a nickel-plated copper hot paddle, a P-type semiconductor die, and a tapered copper wedge together. For example, the assembled structure may be clamped using a compression fixture (e.g., a wooden clothes pin), and subsequently cured at approximately 200° C. for one hour to effectuate thermal and electrical bonding. Upon completion of the curing step, for example, the bonded assembly forms a unitary “coupon” component configured for integration into a superconductive ring (e.g., the TEGASS 1300) and/or solid-state thermoelectric generator (e.g., the SSG 105).

Next, a ring is formed with the coupons and a mica insulator is inserted between two coupons to form a break in the superconductive ring in step 1740. For example, a mica (e.g., insulating) die-sized wafer may be inserted to electrically separate the super conducting ring at one place. In step 1745, each side of the break is connected to a low conductivity switching structure, and the method 1700 ends. At each side of the parted ring, for example, connections will be made to an electronic, low conductive switching structure (e.g., a 10-switch IPB189N04S-01 Infineon switches, with 1.3 milli-Ohms forwards, 180 Ampere forwards that reverses the direction of the ring's current around a high frequency ferrite “E-core”).

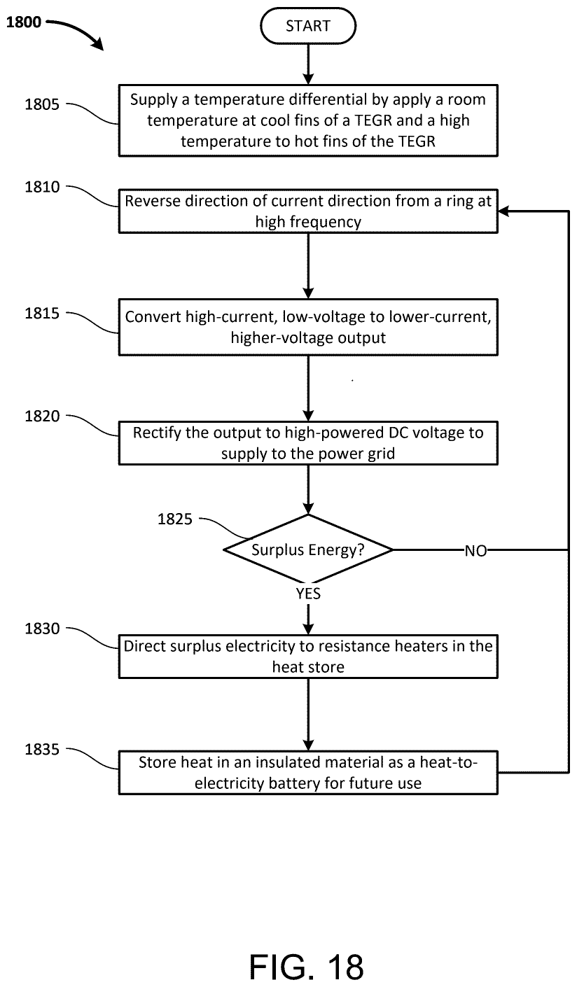

FIG. 18 illustrates a flowchart of an exemplary solid-state electricity generation method 1800. For example, the method 1800 may convert thermal energy into electrical power, and storing surplus electrical energy as heat for future use. In this example, the method 1800 begins when, in step 1805, a temperature differential is supplied by apply a room temperature at cool fins of a thermoelectric ring generator (TERG) and a high temperature to hot fins of the TERG. For example, the temperature differential may be achieved by directing ambient air to the cold metal fin 150 and conducting stored thermal energy from the heat storage of the DTS 120 (e.g., insulated bauxite 1340 of the SSGS 122) to the hot metal fin 160. For example, the high temperature may be supplied by the insulated bauxite 1340. For example, the high temperature may be at least 250° C. higher than the room temperature.

Next, the direction of electrical current flowing through a superconductive ring is reversed at high frequency in step 1810. For example, switching elements may operate at or around 200 KHz to periodically reverse the current out of the superconductive ring, thereby generating a rapidly alternating magnetic field.

In step 1815, the alternating magnetic field induced by the high-frequency current reversal is used as a primary input to a high-frequency transformer. The transformer converts the high-current, low-voltage energy into a lower-current, higher-voltage electrical output suitable for subsequent power conditioning.

In step 1820, the voltage-converted output is rectified into a high-powered direct current (DC) voltage. In some implementations, a diode bridge rectifier may be employed. The rectified DC output may be configured for supply by a 3-phase switching bridge to deliver 3-phase to the grid or to an external power grid or for downstream conversion to a 3-phase alternating current (AC) in phase with an AC grid. In some examples, the voltage-converted output may generate a DC output (e.g., without switching).

In a decision point 1825, it is determined whether surplus electrical energy is available (e.g., in excess of immediate load requirements). For example, the TEGASS 1300 may include a sensing circuit to determine whether the generated power is greater than an instantaneous power demand. If no surplus is present, the step 1810 is repeated. If surplus energy is detected, in step 1830, the surplus electrical energy is directed to one or more resistance heating elements embedded within a thermal energy storage medium. The resistive elements convert the electrical energy into thermal energy. For example, the thermal energy collector 1410 may use the surplus power to power the heating element 1370. In step 1835, the generated heat is stored in an insulated high-capacity thermal storage material (e.g., the insulated bauxite 1340), and the step 1810 is repeated.

Various embodiments may advantageous allow a ring made of mostly copper, along with doped silicon wafers, to be operating in a superconducting critical state (Ct) by allowing heat flowing through the doped silicon wafers. Using a combination of copper and doped silicon wafers and by decreasing drive voltage as shown by FIGS. 11A-D in, for example, 1110, for example, a critical temperature differential between temperatures of +60C and +250C generated by the air flow may advantageously reduce forward resistance of a discrete diode, in the transistor's collector to nearly zero Ohms as shown, for example, in FIGS. 11A-C. It is the p+ and n+ that as shown in, for example, FIGS. 11A-D that creates superconductivity.

Although various embodiments have been described with reference to the figures, other embodiments are possible. For example, the SSGS 1400 may be used with a sun tracking sun farm configured to provide thermal energy to the thermal energy collector 1410. For example, the SSGS 1400 may be installed in a power utility company's right of way. For example, the SSGS 1400 may contribute in reducing a global atmospheric carbon concentration.

For example, in some implementations, a cluster of generator systems 1505 (e.g., including SSGs 105) and the sea freight container 1505 may be clustered together. At least one SSG 105 of the cluster may be selected as a control generator. The other SSGs 105 may be configured (e.g., operably coupled) to the control SSG such that they operate in synchrony with the control SSG. For example, the control SSG may be operated (e.g., turned on, turned off, electrically coupled to a power grid, decoupled from a power grid, output frequency adjusted, output phase adjusted, output amplitude adjusted) and the other SSGs in the cluster may automatically adjust likewise. For example, in some implementations, a generation network may be deployed and advantageously operated as a single unit (e.g., remotely, programmatically, manually).

In some implementations, for example, a power grid 115 may be a regional power grid. In some examples, the power grid 115 may be a local (e.g., building wide, campus wide) power grid. In some examples, the power grid 115 may be a single load. For example, the power grid 115 may operate at 50 and/or 60 Hz. The power grid 115 may, for example, operate at a predetermined voltage(s) (e.g., 120V, 240V, 408V, 480V, 2400V, multiple kV). A grid ready module (e.g., grid ready module 110) may, for example, convert an output of a SSG (e.g., SSG 105) to a corresponding voltage, frequency, and/or phase (e.g., single phase, three-phase). As an illustrative example, three phase energy may be output through three transformers to a power grid. Each leg may, by way of example and not limitation, be output from the grid ready module(s) at 440V and/or up to 800 A (as an illustrative example). In this illustrative example, 440V×3 phase×800 A=1,056,000W. Accordingly, for example, an SSG-based system may be configured to generate 1 MW of power for 1 month or more, 7.2E8 W-hours. The output may be electrically coupled and/or grounded in a target delivery configuration (e.g., wye, delta).

In some implementations an SSGS (e.g., SSGS 122) and/or SSG (e.g., SSG 105) may be portable. For example, a portable generator (e.g., SSGS+SSG) may be configured to be mounted on a vehicle. The vehicle may, for example, be powered (e.g., electrically) by the SSGS releasing thermal energy to the SSG. The SSG may be electrically coupled, for example, to a prime mover of the vehicle (e.g., electric motor driving wheels, pneumatics, and/or hydraulics). The SSGS may, for example, be replaced periodically (e.g., at predetermined ‘swap stations’) for a ‘charged’ SSGS (e.g., a heated SSGS), such as after being depleted (e.g., thermal heat transferred across an SSG to generate electricity). The SSGS may, for example, be interchanged alone and/or with the SSG (e.g., as a single unit). Accordingly, energy may advantageously be stored and/or transported as thermal energy and converted on-demand to electrical energy.

Although an exemplary system has been described with reference to FIGS. 8-10, other implementations may be deployed in other industrial, scientific, medical, commercial, and/or residential applications. In some implementations, the SETS 800 may be moved by air cargo. For example, the Armed Forces may transport the SETS 800 to generate electricity on the battlefield. In some implementations, the SETS 800 may be used on the moon to generate electricity for space stations using solar and wind power stored in the SSGS 122. For example, the SETS 800 may be configured to power vehicles, railroads, airplanes, and other transportation vehicles. In some implementations, the SETS 800 may be used to power cities and/or regions with loss of power due to, for example, natural disasters.

Some systems may be implemented as a computer system that can be used with various implementations. For example, various implementations may include digital circuitry, analog circuitry, computer hardware, firmware, software, or combinations thereof. Apparatus can be implemented in a computer program product tangibly embodied in an information carrier, e.g., in a machine-readable storage device, for execution by a programmable processor; and methods can be performed by a programmable processor executing a program of instructions to perform functions of various embodiments by operating on input data and generating an output. Various embodiments can be implemented advantageously in one or more computer programs that are executable on a programmable system including at least one programmable processor coupled to receive data and instructions from, and to transmit data and instructions to, a data storage system, at least one input device, and/or at least one output device. A computer program is a set of instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

Suitable processors for the execution of a program of instructions include, by way of example, both general and special purpose microprocessors, which may include a single processor or one of multiple processors of any kind of computer. Generally, a processor will receive instructions and data from a read-only memory or a random-access memory or both. The essential elements of a computer are a processor for executing instructions and one or more memories for storing instructions and data. Generally, a computer will also include, or be operatively coupled to communicate with, one or more mass storage devices for storing data files; such devices include magnetic disks, such as internal hard disks and removable disks; magneto-optical disks; and optical disks. Storage devices suitable for tangibly embodying computer program instructions and data include all forms of non-volatile memory, including, by way of example, semiconductor memory devices, such as EPROM, EEPROM, and flash memory devices; magnetic disks, such as internal hard disks and removable disks; magneto-optical disks; and CD-ROM and DVD-ROM disks. The processor and the memory can be supplemented by, or incorporated in, ASICs (application-specific integrated circuits).

Various examples of modules may be implemented using circuitry, including various electronic hardware. By way of example and not limitation, the hardware may include transistors, resistors, capacitors, switches, integrated circuits, other modules, or some combination thereof. In various examples, the modules may include analog logic, digital logic, discrete components, traces and/or memory circuits fabricated on a silicon substrate including various integrated circuits (e.g., FPGAs, ASICs), or some combination thereof. In some embodiments, the module(s) may involve execution of preprogrammed instructions, software executed by a processor, or some combination thereof. For example, various modules may involve both hardware and software.

In an illustrative aspect, a thermoelectric generator may include a heat generation module. For example, the thermoelectric generator may include a thermoelectric generator ring coupled to the heat generation module, and configured to generate an electric current based on a differential temperature received from the heat generation module. For example, the thermoelectric generator ring may include a plurality of thermoelectric coupons forming a ring on a plane.

For example, each of the plurality of thermoelectric coupons may include a p-type impurity diffused silicon semiconductors (IDSS) and an n-type IDSS operably coupled in series forming the ring. For example, the ring may be configured such that opposing surfaces of the n-type IDSS and the p-type IDSS of each of the plurality of thermoelectric coupons may be electrically coupled to corresponding surfaces of each adjacent thermoelectric coupon of the plurality of thermoelectric coupons.

For example, each of the p-type IDSS and the n-type IDSS may include impurities distributed at the opposing surfaces of a silicon semiconductor wafer. For example, the impurities may be distributed at a higher concentration of the opposing surfaces of the corresponding IDSS than at a center of thickness of the corresponding IDSS. For example, in a current generation mode, the heat generation module transfer a differential temperature at the opposing surfaces of the plurality of thermoelectric coupons such that electrical power may be generated to a power grid.

For example, the heat generation module may include a heating element. For example, the heat generation module may include a plurality of heated substances coupled to the heating element and insulated by an insulation layer. For example, the heat generation module may include a heat transfer module configured to transfer thermal energy stored in the plurality of heated substances to the thermoelectric generator ring.

For example, the plurality of heated substances may include insulated bauxite.

For example, the insulation layer may include one or more vermiculite boards.

For example, the heating element may be configured to receive heat from a thermal energy collector coupled to a solar energy source, and an excess energy collection module. For example, the excess energy collection module may be configured to generate heat energy at the heating element as a function of the electrical power generated in excess of a demand of the power grid.

For example, the heating element may include a resistance heater.

For example, the opposing surfaces of each of the p-type IDSS and the n-type IDSS may include an entry side and an exit side. For example, the thermoelectric generator ring may include a plurality of hot metal fins, each corresponds to one of the plurality of thermoelectric coupons. For example, the thermoelectric generator ring may include a plurality of cold metal fins, each corresponds to one of the plurality of thermoelectric coupons. For example, each cold metal fin may be coupled between the exit side of a corresponding n-type IDSS and the entry side of a corresponding p-type IDSS. For example, each hot metal fin may be coupled in a proximal end between the exit side of a corresponding p-type IDSS and the entry side of a corresponding n-type IDSS, and operably thermally coupled to the heat transfer module in a distal end.

For example, the heat transfer module may include a stainless steel exhaust piping thermally coupled to the plurality of hot metal fins. For example, the heat transfer module may include an air blower coupled to the stainless steel exhaust piping, configured transfer ambient air through the plurality of heated substances to the plurality of hot metal fins, such that the differential temperature may be a difference between a temperature of the plurality of hot metal fins heated by hot air flowing through the stainless steel exhaust piping and a room temperature at the plurality of cold metal fins.

For example, the differential temperature may be created between less than 500° C. at the plurality of hot metal fins, and higher than 5° C. at the plurality of cold metal fins.

For example, the thermoelectric generator ring may include a break connected to a power converter. For example, the power converter may include a dielectric mica die separating a ring of the plurality of thermoelectric coupons. For example, the power converter may include a voltage up-converter circuit connected at either side of the dielectric mica die, and each configured to drive a primary current through a DC-to-DC up-converter system.

For example, the thermoelectric generator ring may include copper.

For example, each of the voltage up-converter circuits may be connected to a switch. For example, the power converter may be configured to operate the switch in a high switching frequency, such that a ring current may be induced in the thermoelectric generator ring.

For example, the n-type IDSS may include a buried collector region comprising heavily doped N-type material. For example, the n-type IDSS may include an epitaxial layer surrounding the buried collector region and comprising a lightly doped N-type material. For example, the n-type IDSS may include a top-side collector contact disposed on a top-side of the epitaxial layer. For example, the n-type IDSS may include an ohmic contact disposed to connect the buried collector region to the top-side collector contact through the epitaxial layer. For example, the ohmic contact may include a non-measurable resistance in a forward current direction when the ring current induced. For example, the ring current may be increased above a predetermined threshold induced by the high switching frequency.

In an illustrative aspect, a mobile solid-state generator may include the thermoelectric generator configured to be fitted within a 20-feet sea freight container. For example, the plurality of heated substances may be preloaded with a predetermined quantum of thermal energy. For example, the mobile solid-state generator may include a transformer connector configured as an output port of the electrical power, such that the mobile solid-state generator may be configured to be quickly deployed to the power grid at a local transformer station.

For example, the predetermined quantum of thermal energy may include a month worth of thermal energy to generate a 1-MW power supply.

In an illustrative aspect, a hybrid jet engine may include a forward-mounted fan. For example, the hybrid jet engine a low-pressure turbine and a burner chamber configured to drive the forward-mounted fan. For example, the hybrid jet engine may include an electric motor configured to collectively drive the forward-mounted fan with the low-pressure turbine and the burner chamber. For example, the hybrid jet engine may include the thermoelectric generator configured to supply the electrical power to the electric motor.

The hybrid jet engine, for example, may include a controller configured to dynamically regulate the electrical power supplied to the electric motor. For example, power in excess of a demand of the electric motor may be supplied to the heating element, such that thermal energy may be generated to be stored in the plurality of heated substances based on the power in excess.

In an illustrative aspect, a thermoelectric generator ring operation method may include provide the thermoelectric generator. For example, the thermoelectric generator ring operation method may include supply a temperature differential to the thermoelectric generator by applying a room temperature at the plurality of cold metal fins of the thermoelectric generator ring and a high temperature to the plurality of hot metal fins of the thermoelectric generator ring.

For example, the thermoelectric generator ring operation method may include reverse a ring current direction at a high frequency of at least 100 kHz. For example, the thermoelectric generator ring operation method may include generate the electrical power to the power grid. For example, thermoelectric generator ring operation method may include direct excess electricity to the heating element of the heat generation module. For example, the thermoelectric generator ring operation method may include store thermal energy generated by the heating element in the plurality of heated substances as a heat-to-electricity battery for future use.

For example, the differential temperature may be created between less than 500° C. at the plurality of hot metal fins, and higher than 5° C. at the plurality of cold metal fins.

The thermoelectric generator ring operation method may include preloading the heat-to-electricity battery with a month worth of thermal energy to generate a 1-MW power supply.

A number of implementations have been described. Nevertheless, it will be understood that various modifications may be made. For example, advantageous results may be achieved if the steps of the disclosed techniques were performed in a different sequence, or if components of the disclosed systems were combined in a different manner, or if the components were supplemented with other components. Accordingly, other implementations are contemplated within the scope of the following claims.

What is claimed is:

1. A thermoelectric generator comprising:
a heat generation module; and,
a thermoelectric generator ring coupled to the heat generation module, and configured to generate an electric current based on a differential temperature received from the heat generation module, wherein:
the thermoelectric generator ring comprises a plurality of thermoelectric coupons forming a ring on a plane, and,
each of the plurality of thermoelectric coupons comprises a p-type impurity diffused silicon semiconductors (IDSS) and an n-type IDSS operably coupled in series forming the ring, wherein the ring is configured such that opposing surfaces of the n-type IDSS and the p-type IDSS of each of the plurality of thermoelectric coupons are electrically coupled to corresponding surfaces of each adjacent thermoelectric coupon of the plurality of thermoelectric coupons, and each of the p-type IDSS and the n-type IDSS comprises:
impurities distributed at the opposing surfaces of a silicon semiconductor wafer, wherein the impurities are distributed at a higher concentration of the opposing surfaces of the corresponding IDSS than at a center of thickness of the corresponding IDSS such that,
in a current generation mode, the heat generation module transfer a differential temperature at the opposing surfaces of the plurality of thermoelectric coupons such that electrical power is generated to a power grid.

2. The thermoelectric generator of claim 1, wherein the heat generation module comprises:
a heating element;
a plurality of heated substances coupled to the heating element and insulated by an insulation layer; and,
a heat transfer module configured to transfer thermal energy stored in the plurality of heated substances to the thermoelectric generator ring.

3. The thermoelectric generator of claim 2, wherein the plurality of heated substances comprises insulated bauxite.

4. The thermoelectric generator of claim 2, wherein the insulation layer comprises one or more vermiculite boards.

5. The thermoelectric generator of claim 2, wherein the heating element is configured to receive heat from a thermal energy collector coupled to a solar energy source, and an excess energy collection module, wherein the excess energy collection module is configured to generate heat energy at the heating element as a function of the electrical power generated in excess of a demand of the power grid.

6. The thermoelectric generator of claim 2, wherein the heating element comprises a resistance heater.

7. The thermoelectric generator of claim 2, wherein the opposing surfaces of each of the p-type IDSS and the n-type IDSS comprise an entry side and an exit side, and the thermoelectric generator ring comprises:
a plurality of hot metal fins, each corresponds to one of the plurality of thermoelectric coupons; and,
a plurality of cold metal fins, each corresponds to one of the plurality of thermoelectric coupons, wherein:
each cold metal fin is coupled between the exit side of a corresponding n-type IDSS and the entry side of a corresponding p-type IDSS; and,
each hot metal fin is coupled in a proximal end between the exit side of a corresponding p-type IDSS and the entry side of a corresponding n-type IDSS, and operably thermally coupled to the heat transfer module in a distal end.

8. The thermoelectric generator of claim 7, wherein the heat transfer module comprises:
a stainless steel exhaust piping thermally coupled to the plurality of hot metal fins; and,
an air blower coupled to the stainless steel exhaust piping, configured transfer ambient air through the plurality of heated substances to the plurality of hot metal fins, such that the differential temperature is a difference between a temperature of the plurality of hot metal fins heated by hot air flowing through the stainless steel exhaust piping and a room temperature at the plurality of cold metal fins.

9. The thermoelectric generator of claim 8, wherein the differential temperature is created between less than 500° C. at the plurality of hot metal fins, and higher than 50° C. at the plurality of cold metal fins.

10. The thermoelectric generator of claim 1, wherein the thermoelectric generator ring comprises a break connected to a power converter, wherein the power converter comprises:
a dielectric mica die separating a ring of the plurality of thermoelectric coupons; and,
a voltage up-converter circuit connected at either side of the dielectric mica die, and each configured to drive a primary current through a DC-to-DC up-converter system.

11. The thermoelectric generator of claim 1, wherein the thermoelectric generator ring comprises copper.

12. The thermoelectric generator of claim 10, wherein each of the voltage up-converter circuits is connected to a switch, wherein the power converter is configured to operate the switch in a high switching frequency, such that a ring current is induced in the thermoelectric generator ring.

13. The thermoelectric generator of claim 12, wherein the n-type IDSS comprises:
a buried collector region comprising heavily doped N-type material;
an epitaxial layer surrounding the buried collector region and comprising a lightly doped N-type material;
a top-side collector contact disposed on a top-side of the epitaxial layer; and,
an ohmic contact disposed to connect the buried collector region to the top-side collector contact through the epitaxial layer, wherein the ohmic contact comprises a non-measurable resistance in a forward current direction when the ring current induced, wherein the ring current is increased above a predetermined threshold induced by the high switching frequency.

14. A mobile solid-state generator comprising:
the thermoelectric generator of claim 2 configured to be fitted within a 20-feet sea freight container, wherein the plurality of heated substances is preloaded with a predetermined quantum of thermal energy; and,
a transformer connector configured as an output port of the electrical power, such that the mobile solid-state generator is configured to be quickly deployed to the power grid at a local transformer station.

15. The mobile solid-state generator of claim 14, wherein the predetermined quantum of thermal energy comprises a month worth of thermal energy to generate a 1-MW power supply.

16. A hybrid jet engine, comprising:
a forward-mounted fan;
a low-pressure turbine and a burner chamber configured to drive the forward-mounted fan;
an electric motor configured to collectively drive the forward-mounted fan with the low-pressure turbine and the burner chamber; and,
the thermoelectric generator of claim 2 configured to supply the electrical power to the electric motor.

17. The hybrid jet engine of claim 16, further comprising a controller configured to dynamically regulate the electrical power supplied to the electric motor, wherein power in excess of a demand of the electric motor is supplied to the heating element, such that thermal energy is generated to be stored in the plurality of heated substances based on the power in excess.

18. A thermoelectric generator ring operation method comprises:
provide the thermoelectric generator according to claim 7;
supply a temperature differential to the thermoelectric generator by applying a room temperature at the plurality of cold metal fins of the thermoelectric generator ring and a high temperature to the plurality of hot metal fins of the thermoelectric generator ring;
reverse a ring current direction at a high frequency of at least 100 kHz;
generate the electrical power to the power grid;
direct excess electricity to the heating element of the heat generation module; and,
store thermal energy generated by the heating element in the plurality of heated substances as a heat-to-electricity battery for future use.

19. The thermoelectric generator ring operation method of claim 18, wherein the differential temperature is created between less than 500° C. at the plurality of hot metal fins, and higher than 50° C. at the plurality of cold metal fins.

20. The thermoelectric generator ring operation method of claim 18, further comprises preloading the heat-to-electricity battery with a month worth of thermal energy to generate a 1-MW power supply.
